(19) United States
(12) Patent Application Publication
(10) Pub. No.: US 2026/0343905 A1
(43) Pub. Date: Oct. 29, 2026

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Sheng-An Kuo, Hsinchu (TW); Chen-Sheng Lin, Taoyuan City (TW); Min-Chien Hsiao, Taichung City (TW); Chao-Wen Shih, Zhubei City (TW); Kuo-Chiang Ting, Hsinchu (TW); Yen-Ming Chen, Chu-Pei City (TW)

(21) Appl. No.: 19/735,725

(22) Filed: Jul. 9, 2026

Related U.S. Application Data
(63) Continuation of application No. 18/400,949, filed on Dec. 29, 2023.

(51) Int. Cl. H10B 80/00; H10W 42/00; H10W 90/00; H10W 80/00; H10W 90/20

(52) U.S. Cl. CPC H10B 80/00; H10W 42/00; H10W 42/121; H10W 90/00; H10W 80/211; H10W 80/312; H10W 80/327; H10W 90/297; H10W 90/792

(57) ABSTRACT

Semiconductor devices and methods of manufacture are presented herein. A method includes bonding a first semiconductor die to a first side of a first semiconductor device, the first semiconductor device including a first region of active circuitry and a second region of active circuitry that is electrically isolated from the first region of active circuitry, bonding a second semiconductor die to the first side of the first semiconductor device adjacent to the first semiconductor die, bonding a local interconnect die to the first side of the first semiconductor device between the first semiconductor die and the second semiconductor die, wherein the local interconnect die electrically connects the first region of active circuitry to the second region of active circuitry, and forming a redistribution structure over a second of the first semiconductor device opposite the first side of the first semiconductor device.

### CROSS-REFERENCE TO RELATED APPLICATIONS

This application is a continuation of U.S. Patent Application No. 18/400,949, filed on Dec.29, 2023 and entitled “Semiconductor Devices And Methods Of Manufacture,” which application is incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20nm node), which allows more components to be integrated into a given area. As the demand for miniaturization, higher speed and greater bandwidth, as well as lower power consumption and latency has grown recently, there has grown a need for smaller and more creative packaging techniques of semiconductor dies.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8 illustrates a semiconductor wafer with semiconductor devices attached to the semiconductor wafer forming a first semiconductor package, in accordance with some embodiments.

FIG. 9 illustrates a top down cross section view of the first semiconductor package, in accordance with some embodiments.

FIGS. 10-18 illustrate a formation of a second semiconductor package with a local interconnect first process, in accordance with some embodiments.

FIG. 19 illustrates a top down cross section view of the second semiconductor package, in accordance with some embodiments.

FIGS. 20-30 illustrate a formation of a third semiconductor package with a local interconnect second process, in accordance with some embodiments.

FIG. 31 illustrates a top down cross section view of the third semiconductor package, in accordance with some embodiments.

FIGS. 32A illustrates the first semiconductor package with through substrate via guard rings and deep trench capacitors, in accordance with some embodiments.

FIG. 32B illustrates a top down section view of the through substrate via guard rings around the through substrate vias, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to bonding various device wafers or semiconductor devices in a front side to front side orientation (sometimes referred to as face-to-face bonding). The front side to front side orientation allows for a backside redistribution structure to be formed in combination with local interconnect structures to provide additional connection paths between active circuitry. Such an order of steps and their resulting structures provides an improved process and structure that helps to reduce or eliminate peeling of dielectric layers that can otherwise occur.

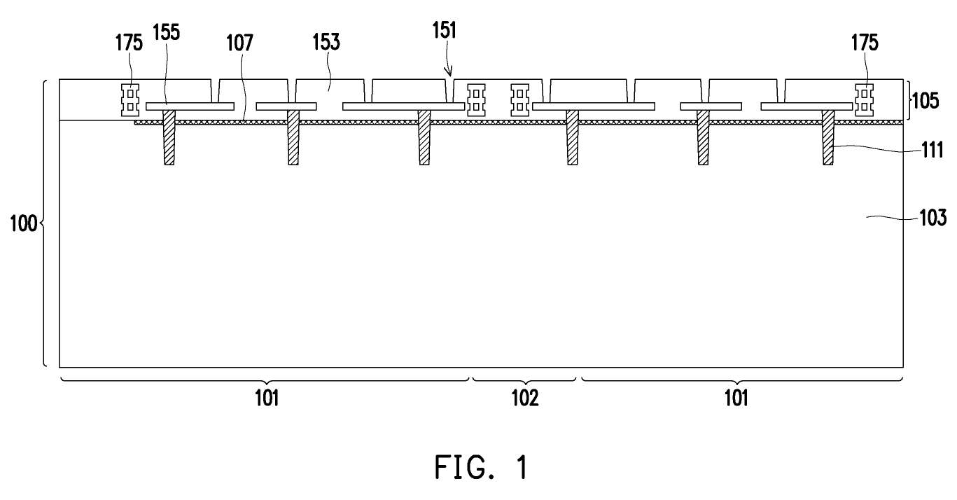

With reference now to FIG. 1, a semiconductor wafer 100 is illustrated with multiple first semiconductor device regions 101 formed with and over the semiconductor wafer 100. In a particular embodiment, the first semiconductor device regions 101 may be a memory device, such as a wide I/O dynamic random access memory (DRAM) device which has a large number of I/O interfaces, such as greater than 256 interfaces, so that a large bandwidth of data may be realized even at low clock speeds. However, the first semiconductor device regions 101 may also be any other suitable type of memory device with a high rate of data transfer, such as an LPDDRn memory device or the like, that has a high rate of data transfer, or may be any other suitable device, such as logic dies, central processing unit (CPU) dies, input/output dies, combinations of these, or the like. Additionally, the semiconductor wafer 100 may be received by the manufacturer from a third party manufacturer, or may be manufactured in house.

In an embodiment the first semiconductor device regions 101 may comprise a first substrate 103, first active devices 107, and first metallization layers 105. The first substrate 103 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

The first active devices 107 comprise a wide variety of active devices and passive devices such as capacitors, resistors, inductors and the like that may be used to generate the desired structural and functional requirements of the design for the first semiconductor device regions 101. The first active devices 107 may be formed using any suitable methods either within or else on the first substrate 103.

The first metallization layers 105 are formed over the first substrate 103 and the first active devices 107 and are designed to connect the various active devices to form functional circuitry. In an embodiment the first metallization layers 105 are formed of first alternating layers of dielectric material 153 (e.g., low-k dielectric materials, extremely low-k dielectric material, ultra-low-k dielectric materials, combinations of these, or the like) and first conductive structures 155 (e.g., conductive lines and vias). In an embodiment, the first metallization layers 105 may be formed through any suitable process (such as deposition, damascene, dual damascene, etc.). In an embodiment there may be four layers of metallization separated from the first substrate 103 by at least one interlayer dielectric layer (ILD), but the precise number of first metallization layers 105 is dependent upon the design of the first semiconductor device regions 101.

First through substrate vias (TSVs) 111 may be formed within the first substrate 103 and, if desired, one or more layers of the first metallization layers 105, in order to provide electrical connectivity from a front side of the first substrate 103 to a backside of the first substrate 103. In an embodiment the first TSVs 111 may be formed by initially forming through silicon via openings into the first substrate 103 and, if desired, any of the overlying first metallization layers 105 (e.g., after the desired first metallization layer 105 has been formed but prior to formation of the next overlying first metallization layer 105). The TSV openings may be formed by applying and developing a suitable photoresist and removing portions of the underlying materials that are exposed to a desired depth. The TSV openings may be formed so as to extend into the first substrate 103 to a depth greater than the eventual desired height of the first substrate 103. Accordingly, while the depth is dependent upon the overall designs, the depth may be between about 20 μm and about 200 μm, such as a depth of about 50 μm.

Once the TSV openings have been formed within the first substrate 103 and or any first metallization layers 105, the TSV openings may be lined with a liner. The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may be used. Additionally, the liner may be formed to a thickness of between about 0.1 μm and about 5 μm, such as about 1 μm.

Once the liner has been formed along the sidewalls and bottom of the TSV openings, a barrier layer may be formed and the remainder of the TSV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer, filling and overfilling the TSV openings. Once the TSV openings have been filled, excess liner, barrier layer, seed layer, and first conductive material outside of the TSV openings may be removed through a planarization process such as chemical mechanical polishing (CMP), although any suitable removal process may be used.

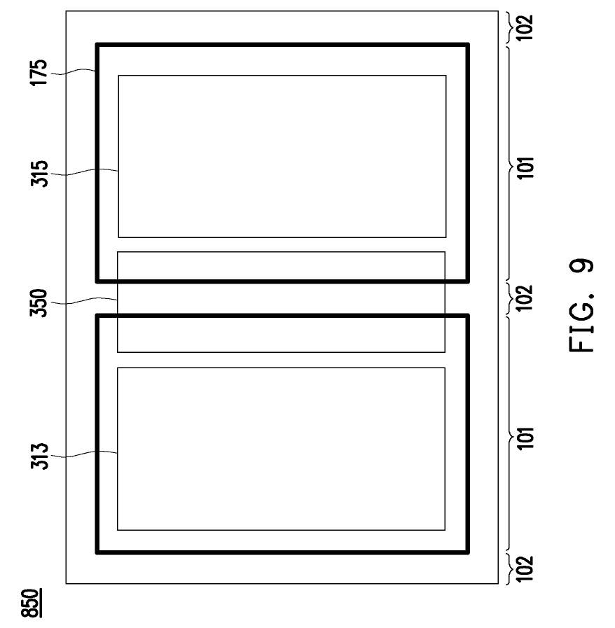

In some embodiments, one or more seal rings 175 are located at peripheries of each of the first semiconductor device regions 101. Each of the seal rings 175 may be disposed in a loop (see e.g., FIG. 9) that encircles functional metallization patterns (e.g., circuitry) in each of the first semiconductor device regions 101. In an embodiment, the seal rings 175 may further act as a boundary zone and as such, the semiconductor wafer 100 may not include any functional circuitry outside of the seal rings 175. For example, the functional circuitry in each of the first semiconductor device regions 101 may be electrically isolated from each other.

Additionally, intermediate regions 102 is disposed between the adjacent ones of the first semiconductor device regions 101, such as between adjacent seal rings 175. In an embodiment, the intermediate region 102 may be a region with no active circuitry although some structures, such as testing structures, may be formed within the intermediate region 102. In some embodiments, some intermediate regions 102 may serve as scribe line regions through which a singulation process is subsequently performed while other intermediate regions 102 are not scribe lines remain intact in the singulated die. Additionally, in an embodiment, the intermediate region 102 may be defined through a formation of multiple seal rings 175. In an embodiment, the multiple seal rings 175 being formed within the multiple first semiconductor device regions 101.

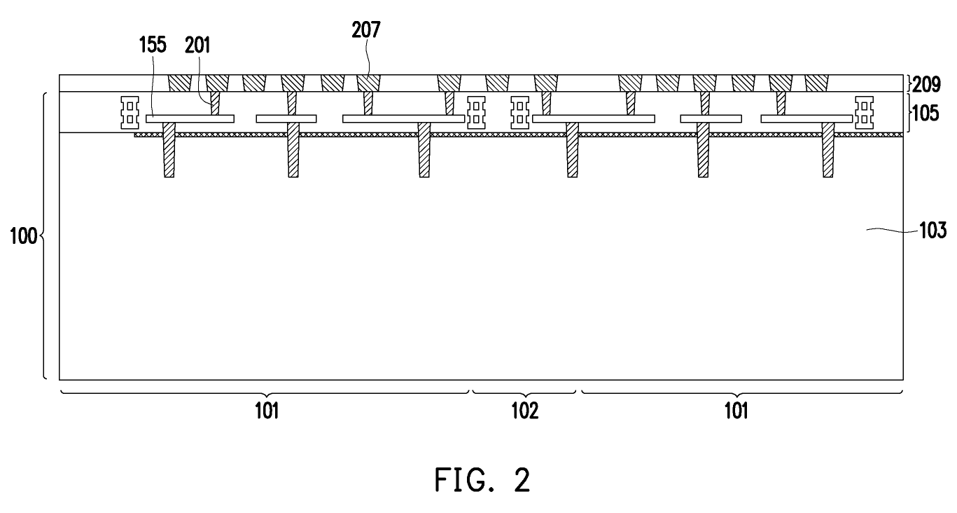

First metallization layer via openings 151 may be formed at a front side of the first metallization layers 105 to prepare for the formation of a first metallization layer vias 201 (not illustrated in FIG. 1, but illustrated in FIG. 2). In an embodiment the first metallization layer via openings 151 may be formed by first applying and patterning a photoresist over the front side of the first metallization layers 105. The photoresist is then used to etch the alternating layers of the dielectric material 153 in order to form the first metallization layer via openings 151. The alternating layers of dielectric material 153 may be etched by dry etching (e.g., reactive ion etching (RIE) or neutral beam etching (NBE)), wet etching, or the like. In accordance with some embodiments of the present disclosure, the etching stops on the first conductive structures 155 of the first metallization layers 105 such that the first conductive structures 155 of the first metallization layers 105 are exposed through the first metallization layer via openings 151 in the first metallization layers 105.

With reference now to FIG. 2, the first metallization layer via openings 151 may be filled to form the first metallization layer vias 201, and a first wafer bond layer 209 may be formed on the first substrate 103 over the first metallization layers 105. In an embodiment, once the first conductive structures 155 of the first metallization layers 105 have been exposed, the first metallization layer vias 201 may be formed in physical and electrical contact with the first conductive structures 155 of first metallization layers 105. In an embodiment the first metallization layer vias 201 may comprise a barrier layer, a seed layer, a fill metal, or combinations thereof (not separately illustrated). For example, the barrier layer may be blanket deposited over the first metallization layers 105. The barrier layer may comprise titanium, titanium nitride, tantalum, tantalum nitride, or the like. The seed layer may be a conductive material such as copper and may be blanket deposited over the barrier layer using processes such as sputtering, evaporation, or plasma-enhanced chemical vapor deposition (PECVD), or the like, depending upon the desired materials. The fill metal may be a conductor such as copper or a copper alloy and may be deposited over the seed layer to fill or overfill the openings through a plating process such as electrical or electroless plating. Once the fill metal has been deposited, excess material of the fill metal, the seed layer, and the barrier layer may be removed from outside of the openings through a planarization process such as chemical mechanical polishing.

In an embodiment, the first wafer bond layer 209 may be used for hybrid bonding (also referred to oxide-to-oxide and metal-to-metal bonding) or fusion bonding (also referred to as oxide-to-oxide bonding). In accordance with some embodiments, the first wafer bond layer 209 is formed of a silicon-containing dielectric material such as silicon oxide, silicon nitride, or the like. The first wafer bond layer 209 may be deposited using any suitable method, such as, atomic layer deposition (ALD), CVD, high-density plasma chemical vapor deposition (HDPCVD), PVD, or the like to a thickness of between about 1 nm and about 1000 nm, such as about 5 nm. However, any suitable material, process, and thickness may be utilized.

Once the first wafer bond layer 209 has been formed, bond openings may be formed within the first wafer bond layer 209 to prepare for the formation of the first conductive bond pads 207. In an embodiment the bond openings may be formed by first applying and patterning a photoresist over the top surface of the first wafer bond layer 209. The photoresist is then used to etch the first wafer bond layer 209 in order to form the openings. The first wafer bond layer 209 may be etched by dry etching (e.g., reactive ion etching (RIE) or neutral beam etching (NBE)), wet etching, or the like. In accordance with some embodiments of the present disclosure, the etching stops on the first metallization layer vias 201 of the first metallization layers 105 such that the first metallization layers 105 are exposed through the openings in the first wafer bond layer 209.

Once the first metallization layer vias 201 have been exposed, the first conductive bond pads 207 may be formed in physical and electrical contact with the first metallization layer vias 201. In an embodiment, the first conductive bond pads 207 may comprise an optional barrier layer, an optional seed layer, a fill metal, or combinations thereof (not separately illustrated). For example, the barrier layer may be blanket deposited over the first metallization layers 105. The barrier layer may comprise titanium, titanium nitride, tantalum, tantalum nitride, or the like. The seed layer may be a conductive material such as copper and may be blanket deposited over the barrier layer using processes such as sputtering, evaporation, or plasma-enhanced chemical vapor deposition (PECVD), or the like, depending upon the desired materials. The fill metal may be a conductor such as copper or a copper alloy and may be deposited over the seed layer to fill or overfill the openings through a plating process such as electrical or electroless plating. Once the fill metal has been deposited, excess material of the fill metal, the seed layer, and the barrier layer may be removed from outside of the openings through a planarization process such as chemical mechanical polishing. However, while a single damascene process has been described for forming the first conductive bond pads 207 and the first metallization layer vias 201, any suitable method, such as a dual damascene process, may also be utilized.

However, the above described embodiment in which the first wafer bond layer 209 is formed, patterned, and the first conductive bond pads 207 is plated into openings before being planarized is intended to be illustrative and is not intended to be limiting upon the embodiments. Rather, any suitable method of formation of the first wafer bond layer 209 and the first conductive bond pads 207 may be utilized. In other embodiments, the first conductive bond pads 207 may be formed first using, for example, a photolithographic patterning and plating process, and then dielectric material is used to gap fill the area around the first conductive bond pads 207 before being planarized using a planarization process. Any such manufacturing process is fully intended to be included within the scope of the embodiments.

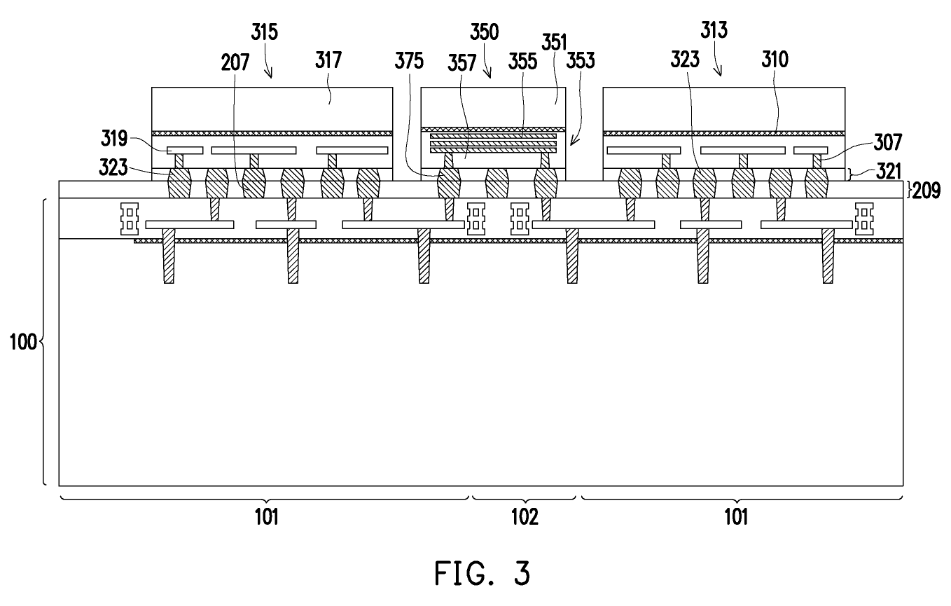

With reference now to FIG. 3, a bonding of a first semiconductor die 313, a second semiconductor die 315, and a first local interconnect die 350 to the first conductive bond pads 207 and the first wafer bond layer 209 is performed. In an embodiment, each of the first semiconductor die 313 and the second semiconductor die 315 may each be a system on chip device, such as a logic device, which is intended to work in conjunction with the first semiconductor device regions 101 (e.g., the wide I/O DRAM devices). However, any suitable functionality, such as logic dies, central processing unit (CPU) dies, input/output dies, combinations of these, or the like, may be utilized.

In an embodiment, the first semiconductor dies 313 and the second semiconductor die 315 may each have second substrates 317, second active devices 301, second metallization layers 319, second metallization layer vias 307, second wafer bond layers 321, and second conductive bond pads 323. In an embodiment, the second metallization layers 319 comprises second alternating layers of dielectric 303 and second conductive structures 305. In an embodiment the second substrates 317, the second active devices 301, the second metallization layers 319, the second metallization layer vias 307, the second wafer bond layers 321, and the second conductive bond pads 323 may be formed similar to the first substrate 103, the first active devices 107, the first metallization layers 105, the first metallization layer vias 201, the first wafer bond layer 209, and the first conductive bond pads 207, respectively, as discussed above. However, in other embodiments these structures may be formed using different processes and different materials.

Once the first semiconductor dies 313 and the second semiconductor die 315 have been prepared, the first semiconductor dies 313 and the second semiconductor die 315 are bonded to the first semiconductor device regions 101 using, for example, metal-to-metal and oxide-to-oxide bonding. In an embodiment the surfaces of the first semiconductor device regions 101 (e.g., the first wafer bond layer 209 and the first conductive bond pads 207) and the surfaces of the first semiconductor die 313 and the second semiconductor die 315 (e.g., the second wafer bond layers 321 and the second conductive bond pads 323) may initially be activated. Activating the top surfaces of the first semiconductor device regions 101, the first semiconductor die 313, and the second semiconductor die 315 may comprise a dry treatment, a wet treatment, a plasma treatment, exposure to an inert gas plasma, exposure to H₂, exposure to N₂, exposure to O₂, or combinations thereof, as examples. In embodiments where a wet treatment is used, an RCA cleaning may be used, for example. In another embodiment, the activation process may comprise other types of treatments. The activation process assists in the hybrid bonding of the first semiconductor device regions 101, first semiconductor die 313 and the second semiconductor die 315.

After the activation process, the first semiconductor die 313 and the second semiconductor die 315 may be placed into contact with the first semiconductor device regions 101. In a particular embodiment in which metal-to-metal and oxide-to-oxide bonding is utilized, the first conductive bond pads 207 is placed into physical contact with the second conductive bond pads 323 while the first wafer bond layer 209 is placed into physical contact with the second wafer bond layers 321. With the activation process chemically modifying the surfaces, the bonding process between the materials is begun upon the physical contact.

Once physical contact has begun the bonding process, the bonding may then be strengthened by subjecting the assembly to a thermal treatment. In an embodiment the first semiconductor device regions 101, the first semiconductor die 313, and the second semiconductor die 315 may be subjected to a temperature between about 200°C and about 400°C to strengthen the bond between the first wafer bond layer 209 and the second wafer bond layers 321. The first semiconductor device regions 101, the first semiconductor die 313, and the second semiconductor die 315 may then be subjected to a temperature at or above the eutectic point for material of the first conductive bond pads 207 and the second conductive bond pads 323. In this manner, fusion of the first semiconductor device regions 101, the first semiconductor die 313, and the second semiconductor die 315 forms a hybrid bonded device.

Additionally, while specific processes have been described to initiate and strengthen the metal-to-metal and oxide-to-oxide bonding between the first semiconductor device regions 101, the first semiconductor die 313, and the second semiconductor die 315, these descriptions are intended to be illustrative and are not intended to be limiting upon the embodiments. Rather, any suitable combination of baking, annealing, pressing, or other bonding processes or combination of processes may be utilized. All such processes are fully intended to be included within the scope of the embodiments.

Also, while metal-to-metal and oxide-to-oxide bonding has been described as one method of bonding the first semiconductor device regions 101 to the first semiconductor die 313 and the second semiconductor die 315, this as well is only intended to be illustrative and is not intended to be limiting upon the embodiments. Rather, any suitable method of bonding, such as solder bonding using, e.g., a ball grid array, may also be utilized. Any suitable method of bonding the first semiconductor device regions 101 to the first semiconductor die 313 and the second semiconductor die 315 may be utilized.

Further, in an embodiment, the first local interconnect die 350 (sometimes referred to as a local silicon interconnect (LSI) or as a silicon bridge) comprises an first interconnect substrate 351 that supports a first interconnect structure 353, which comprises first interconnect metallization patterns 355 (e.g., conductive lines, vias, and conductive pads) in one or more first interconnect dielectric layers 357. The first interconnect metallization patterns 355 and the first interconnect dielectric layers 357 may be formed in a similar manner and form similar materials as discussed with respect to first conductive structures 155 of the first metallization layers 105 and the first alternating layers of dielectric material 153 of the first metallization layers 105, respectively. In an embodiment, the first interconnect substrate 351 may be formed of silicon, such as bulk silicon. In an embodiment, the first interconnect substrate 351 may be formed in a similar manner and from similar materials as the first substrate 103.

In an embodiment, first interconnect conductive pads 375 of the first interconnect metallization patterns 355 along with one of the first interconnect dielectric layers 357 may be used to bond the first local interconnect die 350 to the first wafer bond layer 209 in a similar manner as discussed above with respect to the bonding of the second wafer bond layers 321 and the second conductive bond pads 323 to the first wafer bond layer 209 and the first conductive bond pads 207, respectively.

In an embodiment, the first local interconnect die 350 electrically couples the functional metallization patterns between individual first semiconductor device regions 101. Further, in an embodiment, the first semiconductor die 313 is electrically coupled to the functional metallization pattern of one of the first semiconductor device regions 101 and the second semiconductor die 315 is electrically coupled to the functional metallization pattern of one of the other first semiconductor device regions 101. In an embodiment, the first semiconductor die 313 may be electrically coupled to the second semiconductor die 315 through electrical coupling made by the first local interconnect die 350 between the first semiconductor device regions 101 that the first semiconductor die 313 and the second semiconductor die 315 are electrically coupled to, respectively.

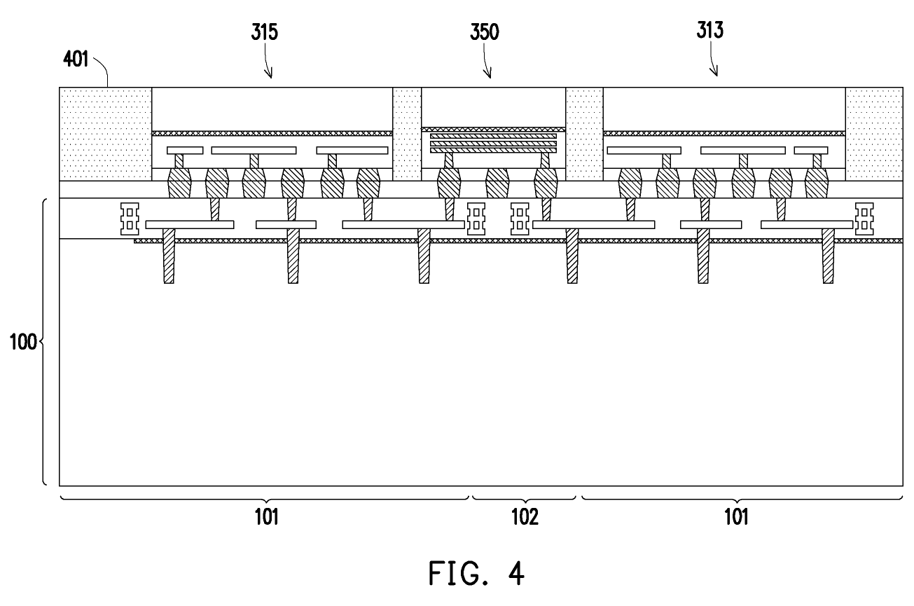

With reference now to FIG. 4, the first semiconductor die 313, the second semiconductor die 315, the first local interconnect die 350, and the first semiconductor device regions 101 may be encapsulated with a first encapsulant 401. In an embodiment, the encapsulation may be performed in a molding device, which may comprise a top molding portion and a bottom molding portion separable from the top molding portion. When the top molding portion is lowered to be adjacent to the bottom molding portion, a molding cavity may be formed for the first semiconductor device regions 101, the first semiconductor die 313, the second semiconductor die 315, and the first local interconnect die 350.

During the encapsulation process the top molding portion may be placed adjacent to the bottom molding portion, thereby enclosing the first semiconductor device regions 101, the first semiconductor die 313, the second semiconductor die 315, and the first local interconnect die 350 within the molding cavity. Once enclosed, the top molding portion and the bottom molding portion may form an airtight seal in order to control the influx and outflux of gasses from the molding cavity. Once sealed, the first encapsulant 401 may be placed within the molding cavity.

The first encapsulant 401 may be an epoxy or a molding compound resin such as polyimide, polyphenylene sulfide (PPS), polyetheretherketone (PEEK), poly ether sulphone (PES), a heat resistant crystal resin, combinations of these, or the like. The first encapsulant 401 may be placed within the molding cavity prior to the alignment of the top molding portion and the bottom molding portion, or else may be injected into the molding cavity through an injection port, using compression molding, transfer molding, or the like.

Once the first encapsulant 401 is placed into the molding cavity such that the first encapsulant 401 encapsulates the first semiconductor device regions 101, the first semiconductor die 313, the second semiconductor die 315, and the first local interconnect die 350, the first encapsulant 401 may be cured in order to harden the first encapsulant 401 for optimum protection. While the exact curing process is dependent at least in part on the particular material chosen for the first encapsulant 401, in an embodiment in which molding compound is chosen as the first encapsulant 401, the curing could occur through a process such as heating the first encapsulant 401 to between about 100 ºC and about 200 ºC, such as about 125 ºC for about 60 sec to about 3000 sec, such as about 600 sec. Additionally, initiators and/or catalysts may be included within the first encapsulant 401 to better control the curing process.

However, as one having ordinary skill in the art will recognize, the curing process described above is merely an exemplary process and is not meant to limit the current embodiments. Other curing processes, such as irradiation or even allowing the first encapsulant 401 to harden at ambient temperature, may also be used. Any suitable curing process may be used, and all such processes are fully intended to be included within the scope of the embodiments discussed herein.

FIG. 4 further illustrates a thinning of the first encapsulant 401 in order to expose the first semiconductor die 313, the second semiconductor die 315, and the first local interconnect die 350 for further processing. The thinning may be performed, e.g., using a mechanical grinding, chemical approaches, or chemical mechanical polishing (CMP) process whereby chemical etchants and abrasives are utilized to react and grind away the first encapsulant 401 so that the first semiconductor die 313, the second semiconductor die 315, and the first local interconnect die 350 have been exposed and the first encapsulant 401 has a thickness of between about 100 μm and about 150 μm. As such, the first semiconductor dies 313, the second semiconductor die 315, and the first local interconnect die 350 may have a planar surface that is also coplanar with the first encapsulant 401. In another embodiment, the grinding may be omitted. For example, if the first semiconductor die 313 and the second semiconductor die 315 are already exposed after encapsulation, the grinding may be omitted.

Furthermore, while the CMP process described above is presented as one illustrative embodiment, it is not intended to be limiting to the embodiments. Any other suitable removal process may be used to thin the first encapsulant 401. For example, a series of chemical etches may be utilized. This process and any other suitable process may be utilized to planarize the first encapsulant 401, and all such processes are fully intended to be included within the scope of the embodiments.

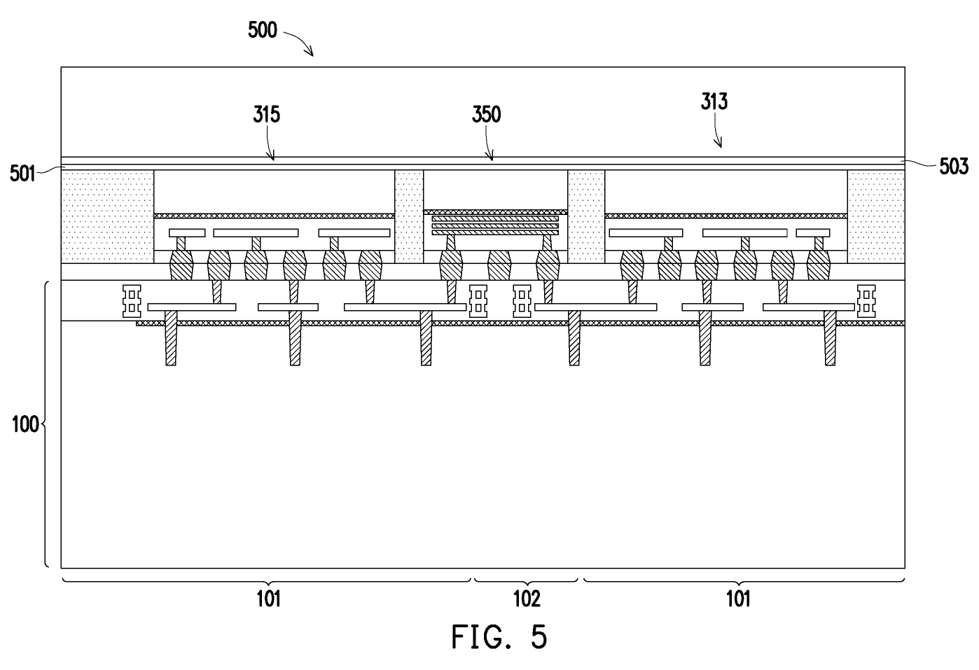

With reference now to FIG. 5, a placement of a first carrier substrate 500 is depicted. In an embodiment, the first carrier substrate 500 comprises, for example, silicon-based materials, such as silicon, glass, or the like. In an embodiment, the first carrier substrate 500 is planar in order to accommodate the attachment of the first semiconductor die 313 and the second semiconductor die 315, which may be attached through a bonding process or through the use of an adhesive layer (not separately illustrated).

In an embodiment, the first carrier substrate 500 is bonded to the first semiconductor die 313 and the second semiconductor die 315. In this embodiment, a first bonding layer 501 may be formed over the planar surface of the first semiconductor die 313 and the second semiconductor die 315. In an embodiment, the first bonding layer 501 may comprise an oxide, such as silicon oxide, silicon oxynitride, the like, or a combination thereof, and may be formed by high density plasma chemical vapor deposition (HDP-CVD), a flowable CVD (FCVD) (e.g., a CVD-based material deposition in a remote plasma system and post curing to make it convert to the oxide), ALD, physical vapor deposition (PVD), the like, or a combination thereof. Other oxide materials formed by any acceptable process may be used to form the first bonding layer 501.

Following the formation of the first bonding layer 501, the first carrier substrate 500 may be bonded to the first bonding layer 501 by a second bonding layer 503 of the first carrier substrate 500. In an embodiment, the second bonding layer 503 is formed over the first carrier substrate 500 in a similar manner and from similar materials as the first bonding layer 501. In accordance with some embodiments, the first carrier substrate 500 comprises silicon, or the like. In an embodiment, the second bonding layer 503 is bonded to the first bonding layer 501 through a dielectric-to-dielectric bonding process (e.g., oxide-to-oxide bonding) forming a dielectric-to dielectric bond (e.g., an oxide-to-oxide bond). In an embodiment, the dielectric-to-dielectric bonding process may include applying a surface treatment to one or more of the first bonding layer 501 and the second bonding layer 503. The surface treatment may include a plasma treatment, which may be applied to an exposed surface of the respective bonding layer. The plasma treatment may be performed in a vacuum environment. After the plasma treatment, the surface treatment may further include a cleaning process (e.g., a rinse with deionized water or the like) that may be applied to one or more of the first bonding layer 501 and the second bonding layer 503. The first carrier substrate 500 is then aligned with the first bonding layer 501 and the two are pressed against each other to initiate a pre-bonding of the first carrier substrate 500 to the first bonding layer 501 over the first semiconductor die 313 and the second semiconductor die 315. The pre-bonding may be performed at room temperature (e.g., between about 21° C and about 25° C). After the pre-bonding, an annealing process may be applied by, for example, heating the first bonding layer 501 and the second bonding layer 503 to a temperature of in a range of 150° C to 500˚ C. The annealing process increases bond strength and triggers the formation of covalent bonds between the first bonding layer 501 and the second bonding layer 503. Other bonding processes, such as ambient bonding, vacuum bonding, or the like may be used in other embodiments.

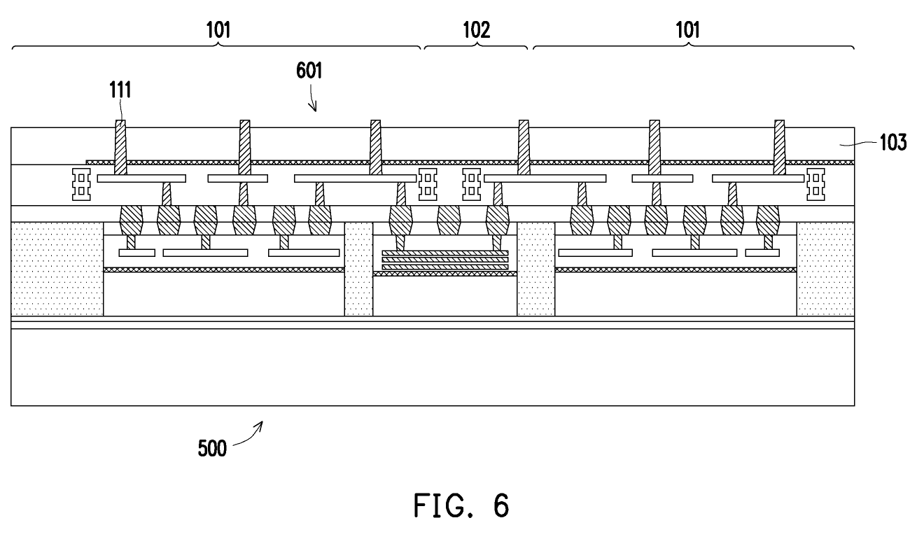

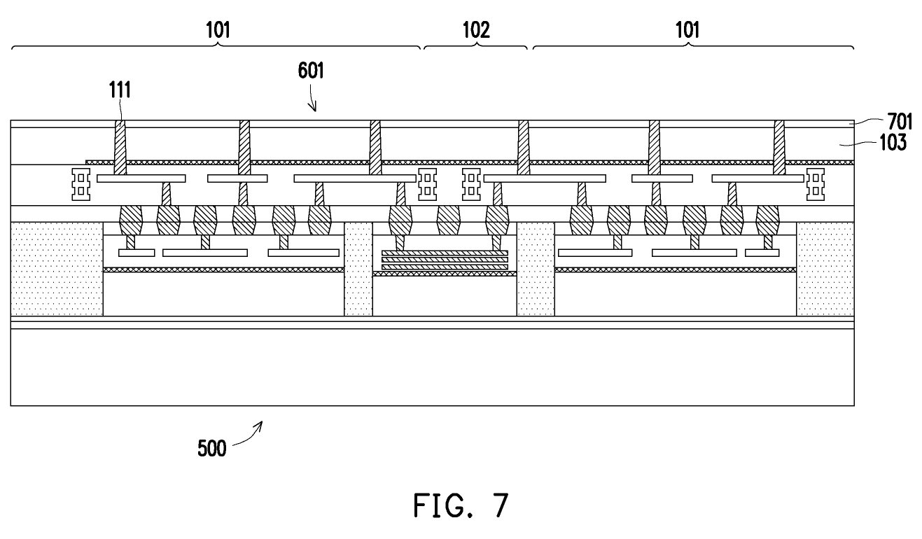

With reference now to FIG. 6, once the first carrier substrate 500 is attached, the second side of the first substrate 103 may be thinned in order to expose the first TSVs 111. In an embodiment, the thinning of the second side of the first substrate 103 may leave the first TSVs 111 exposed. The thinning of the second side of the first substrate 103 may be performed by a planarization process such as CMP or etching. However, any suitable method of thinning the second side of the first substrate 103. In one embodiment, the etching is a time-controlled anisotropic plasma etch process that creates recesses 601 that the first TSVs 111 protrude from. In an embodiment, the recesses 601 may be formed to a sufficient depth as to facilitate the thickness of a subsequently formed first passivation film 701 (not shown in FIG. 6, but illustrated in FIG. 7).

With reference now to FIG. 7, a formation of the first passivation film 701 over the second side of the first substrate 103 is depicted. In an embodiment, the first passivation film 701 may comprise silicon oxide, silicon oxynitride, silicon nitride, or the like. In an embodiment, the first passivation film 701 may be deposited by CVD, ALD, PVD, or the like. Following the deposition of the first passivation film 701 a planarization process may be performed to expose a top surface of the first TSVs 111.

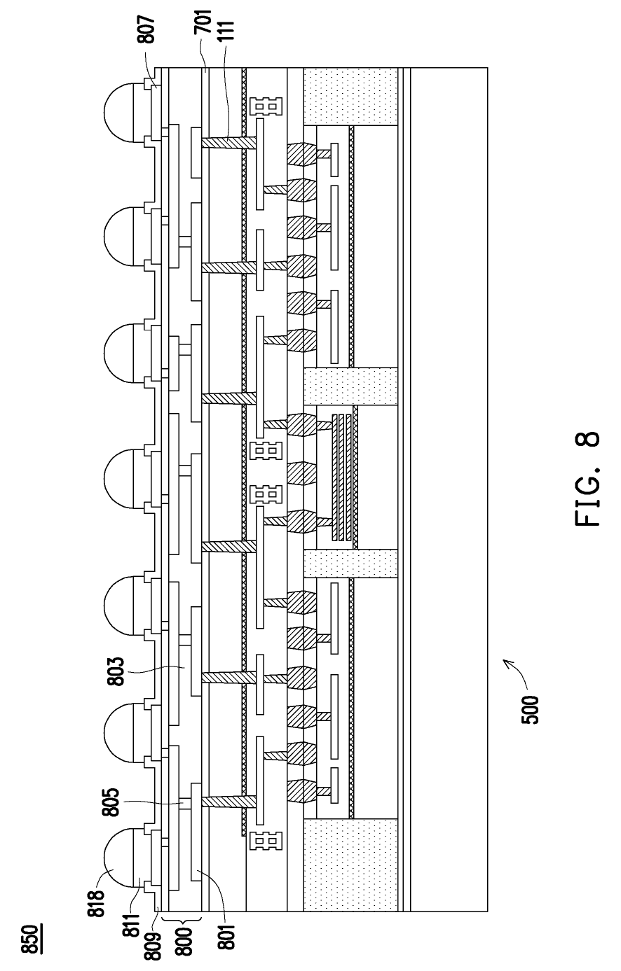

With reference now to FIG. 8, a formation of a first backside redistribution structure 800 is performed. The first backside redistribution structure 800 may include one or more redistribution dielectric layer(s) 803 and respective redistribution metallization layer(s) 801 in the redistribution dielectric layer(s) 803. The redistribution dielectric layer(s) 803 may be, e.g., low-k dielectric layer(s). The redistribution metallization layer(s) 801 may include conductive vias formed between the redistribution metallization layer(s) 801, (e.g., redistribution conductive elements 805). The redistribution metallization layer(s) 801 may be formed of a conductive material, such as a metal, such as copper, cobalt, aluminum, gold, combinations thereof, or the like. The redistribution metallization layer(s) 801 of the first backside redistribution structure 800 may be formed by a damascene process, such as a single damascene process, a dual damascene process, or the like.

In an embodiment, a first metallization contact pad 807 is formed over a top most dielectric layer of the first backside redistribution structure 800. The first metallization contact pad 807 may be formed in a similar manner as the redistribution metallization layer(s) 801. In an embodiment, the first metallization contact pad 807 may be formed to a different thickness than the redistribution metallization layer(s) 801. In an embodiment, a first redistribution passivation layer 809 may be formed over the top most dielectric layer and over the first metallization contact pad 807. The first redistribution passivation layer 809 may be a material such as a nitride, an oxide, a polyimide, a low-temp polyimide, a solder resist, combinations thereof, or the like. Once formed, the first redistribution passivation layer 809 may be patterned (e.g., using a suitable photolithographic and etching process) to expose portions of the first metallization contact pad 807.

In an embodiment, first under bump metallizations (UBM)s 811 are formed for external connection to the first backside redistribution structure 800. The first UBMs 811 have bump portions on and extending along the major surface of the first redistribution passivation layer 809, and have via portions extending through the first redistribution passivation layer 809 to physically and electrically couple the first metallization contact pad 807. The first UBMs 811 may be formed of the same material as the redistribution metallization layer(s) 801.

In an embodiment, first conductive connectors 813 are formed on the First UBMs 811. The first conductive connectors 813 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The first conductive connectors 813 may include a conductive material such as solder, copper, aluminum, gold, nickel, silver, palladium, tin, the like, or a combination thereof. In some embodiments, the first conductive connectors 813 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the first conductive connectors 813 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. The resulting structure depicted in FIG. 8 may be referred to as a first semiconductor package 850.

Subsequently, in some embodiments, the first carrier substrate 500 can be removed, and a singulation process may be performed around peripheries of the illustrated package region. However, the singulation process may not be performed in certain regions intermediate regions 102, such as the region between the two illustrated, first semiconductor device regions 101.

With reference now to FIG. 9, a top down cross section view of the first semiconductor package 850 is depicted. In an embodiment, the seal rings 175 surrounded the active circuitry of the multiple first semiconductor device regions 101 and also respectively completely cover the first semiconductor die 313 and the second semiconductor die 315. In an embodiment, the first local interconnect die 350 overlaps the seal rings 175 defining one of the first semiconductor device regions 101, completely overlaps the intermediate region 102, and overlaps the seal rings 175 defining a different one of the first semiconductor device regions 101.

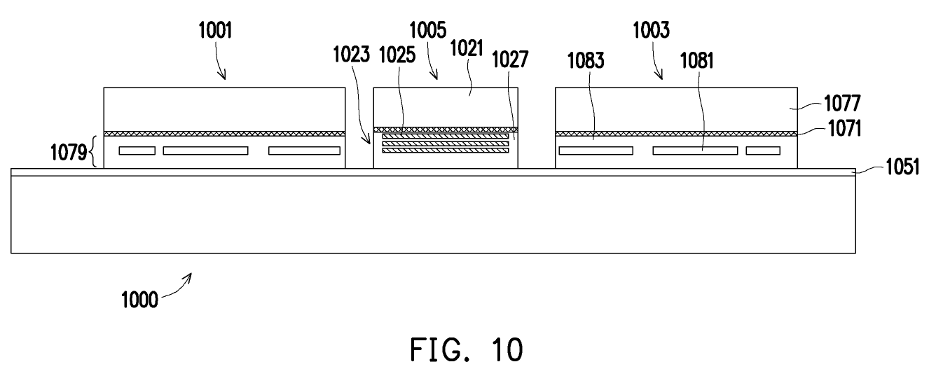

FIGS. 1 through 9 illustrate one specific package configuration, but other configurations are possible. For example, FIGS. 10 through 19 illustrate various intermediate steps of manufacturing a semiconductor package in accordance with some other embodiments. With reference now to FIG. 10, a third semiconductor die 1001, a fourth semiconductor die 1003, and a second local interconnect die 1005 (sometimes referred to as a local silicon interconnect (LSI) or as a silicon bridge)are attached to a second carrier substrate 1000. In an embodiment, each of the third semiconductor die 1001 and the fourth semiconductor die 1003 may each be a system on chip device, such as a logic device. However, any suitable functionality, such as logic dies, central processing unit (CPU) dies, input/output dies, combinations of these, or the like, may be utilized.

In an embodiment the third semiconductor die 1001 and the fourth semiconductor die 1003 may each have third substrates 1077, third active devices 1071, and third metallization layers 1079, the third metallization layers 1079 including third conductive structures 1081 and third alternating layers of dielectric 1083. In an embodiment, the third substrates 1077, the third active devices 1071, and the third metallization layers 1079, may be formed similar to the first substrate 103, the first active devices 107, and the first metallization layers 105, respectively, as described above. However, in other embodiments these structures may be formed using different processes and different materials.

In an embodiment, a front side of the third semiconductor die 1001, a front side of the fourth semiconductor die 1003, and a front side of the second local interconnect die 1005 are bonded to the second carrier substrate 1000. In this embodiment, a third bonding layer 1051 may be formed over the second carrier substrate 1000. In an embodiment, the third bonding layer 1051 may comprise an oxide, such as silicon oxide, silicon oxynitride, the like, or a combination thereof and may be formed by high density plasma chemical vapor deposition (HDP-CVD), a flowable CVD (FCVD) (e.g., a CVD-based material deposition in a remote plasma system and post curing to make it convert to the oxide), ALD, physical vapor deposition (PVD), the like, or a combination thereof. Other oxide materials formed by any acceptable process may be used to form the third bonding layer 1051.

In an embodiment, the alternating dielectric layers of the third metallization layers 1079 is bonded to the third bonding layer 1051 through a dielectric-to-dielectric bonding process (e.g., oxide-to-oxide bonding) forming a dielectric-to dielectric bond (e.g., an oxide-to-oxide bond). The dielectric-to-dielectric bonding process may be carried out in a similar manner as discussed above.

Further, in an embodiment, the second local interconnect die 1005 comprises a second interconnect substrate 1021 that supports a second interconnect structure 1023, which comprises second interconnect metallization patterns 1025 (e.g., conductive lines, vias, and conductive pads) in one or more second interconnect dielectric layers 1027. The second interconnect metallization patterns 1025 and the second interconnect dielectric layers 1027 may be formed in a similar manner and form similar materials as discussed with respect to the first conductive structures 155 of the first metallization layers 105 and the alternating layers of dielectric material 153 of the first metallization layers 105. In an embodiment, the second interconnect substrate 1021 may be formed of silicon, such as bulk silicon. In an embodiment, the second interconnect substrate 1021 may be formed in a similar manner and from similar materials as the first substrate 103. In an embodiment, the second interconnect dielectric layers 1027 are utilized to form dielectric-to-dielectric bonds with the third bonding layer 1051 to bond the second local interconnect die 1005 to the second carrier substrate 1000.

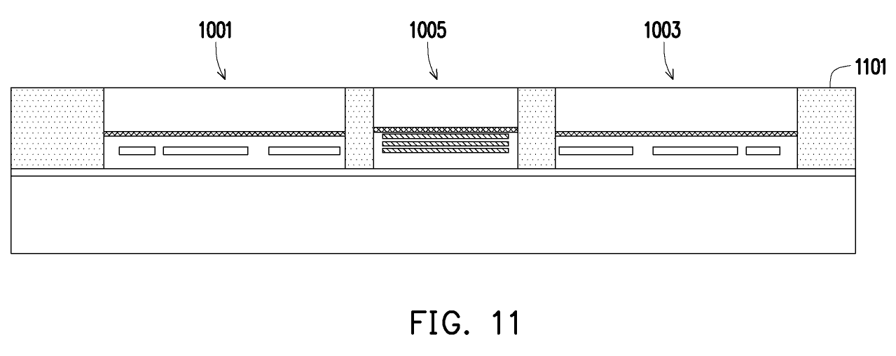

With reference now to FIG. 11, the third semiconductor die 1001, the fourth semiconductor die 1003, and the second local interconnect die 1005 may be encapsulated with a second encapsulant 1101. In an embodiment the encapsulation may be performed in a molding device, which may comprise a top molding portion and a bottom molding portion separable from the top molding portion. When the top molding portion is lowered to be adjacent to the bottom molding portion, a molding cavity may be formed for the third semiconductor die 1001, the fourth semiconductor die 1003, and the second local interconnect die 1005.

During the encapsulation process the top molding portion may be placed adjacent to the bottom molding portion, thereby enclosing the third semiconductor die 1001, the fourth semiconductor die 1003, and the second local interconnect die 1005 within the molding cavity. Once enclosed, the top molding portion and the bottom molding portion may form an airtight seal in order to control the influx and outflux of gasses from the molding cavity. Once sealed, the second encapsulant 1101 may be placed within the molding cavity.

The second encapsulant 1101 may be an epoxy or a molding compound resin such as polyimide, polyphenylene sulfide (PPS), polyetheretherketone (PEEK), poly ether sulphone (PES), a heat resistant crystal resin, combinations of these, or the like. The second encapsulant 1101 may be placed within the molding cavity prior to the alignment of the top molding portion and the bottom molding portion, or else may be injected into the molding cavity through an injection port, using compression molding, transfer molding, or the like.

Once the second encapsulant 1101 is placed into the molding cavity such that the second encapsulant 1101 encapsulates the third semiconductor die 1001, the fourth semiconductor die 1003, and the second local interconnect die 1005, the second encapsulant 1101 may be cured in order to harden the second encapsulant 1101 for optimum protection. While the exact curing process is dependent at least in part on the particular material chosen for the second encapsulant 1101, in an embodiment in which molding compound is chosen as the second encapsulant 1101, the curing could occur through a process such as heating the first encapsulant 401 to between about 100 ºC and about 200 ºC, such as about 125 ºC for about 60 sec to about 3000 sec, such as about 600 sec. Additionally, initiators and/or catalysts may be included within the second encapsulant 1101 to better control the curing process.

However, as one having ordinary skill in the art will recognize, the curing process described above is merely an exemplary process and is not meant to limit the current embodiments. Other curing processes, such as irradiation or even allowing the second encapsulant 1101 to harden at ambient temperature, may also be used. Any suitable curing process may be used, and all such processes are fully intended to be included within the scope of the embodiments discussed herein.

FIG. 11 further illustrates a thinning of the second encapsulant 1101 in order to expose a backside of the third semiconductor die 1001, a backside of the fourth semiconductor die 1003, and a backside of the second local interconnect die 1005 for further processing. The thinning may be performed, e.g., using a mechanical grinding, chemical approaches, or chemical mechanical polishing (CMP) process whereby chemical etchants and abrasives are utilized to react and grind away the second encapsulant 1101 so that the third semiconductor die 1001, the fourth semiconductor die 1003, and the second local interconnect die 1005 have been exposed and the second encapsulant 1101 has a thickness of between about 100 μm and about 150 μm. As such, the third semiconductor die 1001, the fourth semiconductor die 1003, and the second local interconnect die 1005 may have a planar surface that is also coplanar with the second encapsulant 1101.

Furthermore, while the CMP process described above is presented as one illustrative embodiment, it is not intended to be limiting to the embodiments. Any other suitable removal process may be used to thin the second encapsulant 1101. For example, a series of chemical etches may be utilized. This process and any other suitable process may be utilized to planarize the second encapsulant 1101, and all such processes are fully intended to be included within the scope of the embodiments.

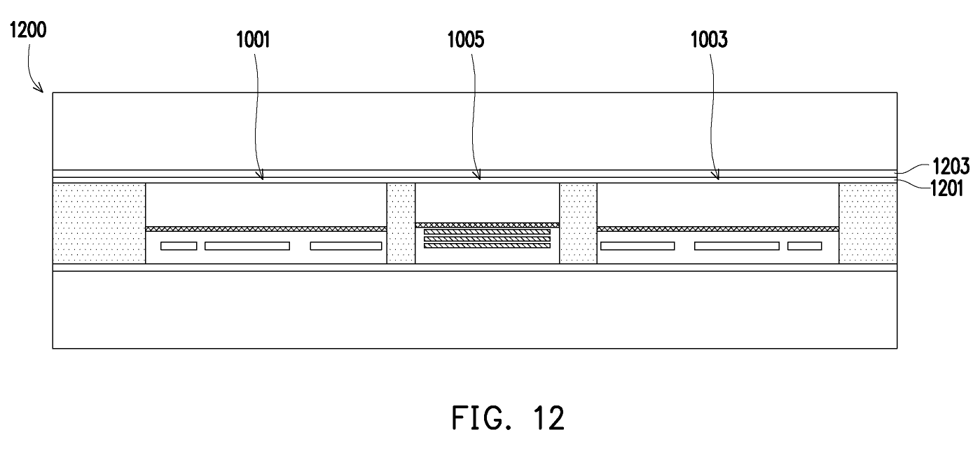

With reference now to FIG. 12, a placement of a third carrier substrate 1200 is depicted. In an embodiment, the third carrier substrate 1200 comprises, for example, silicon-based materials, such as silicon, glass, or the like. In an embodiment, the third carrier substrate 1200 is planar in order to accommodate the attachment of the third semiconductor die 1001 and the fourth semiconductor die 1003, which may be attached through a bonding process or through the use of an adhesive layer (not separately illustrated).

In an embodiment, the third carrier substrate 1200 is bonded to a backside of the third semiconductor die 1001, a backside of the fourth semiconductor die 1003, and a backside of the second local interconnect die 1005. In this embodiment, a fourth bonding layer 1201 may be formed over the planar surface of the third semiconductor die 1001, the fourth semiconductor die 1003, the second local interconnect die 1005, and the second encapsulant 1101. In an embodiment, the fourth bonding layer 1201 may comprise an oxide, such as silicon oxide, silicon oxynitride, the like, or a combination thereof, and may be formed by high density plasma chemical vapor deposition (HDP-CVD), a flowable CVD (FCVD) (e.g., a CVD-based material deposition in a remote plasma system and post curing to make it convert to the oxide), ALD, physical vapor deposition (PVD), the like, or a combination thereof. Other oxide materials formed by any acceptable process may be used to form the fourth bonding layer 1201.

In an embodiment, the third carrier substrate 1200 may be bonded to the fourth bonding layer 1201 by a fifth bonding layer 1203 of the third carrier substrate 1200. In an embodiment, the fifth bonding layer 1203 is formed over the third carrier substrate 1200 in a similar manner and from similar materials as the fourth bonding layer 1201. In accordance with some embodiments, the third carrier substrate 1200 comprises silicon, or the like. In an embodiment, the fifth bonding layer 1203 is bonded to the fourth bonding layer 1201 through a dielectric-to-dielectric bonding process (e.g., oxide-to-oxide bonding) forming a dielectric-to dielectric bond (e.g., an oxide-to-oxide bond). The dielectric-to-dielectric bonding process may be carried out in a similar manner as discussed above.

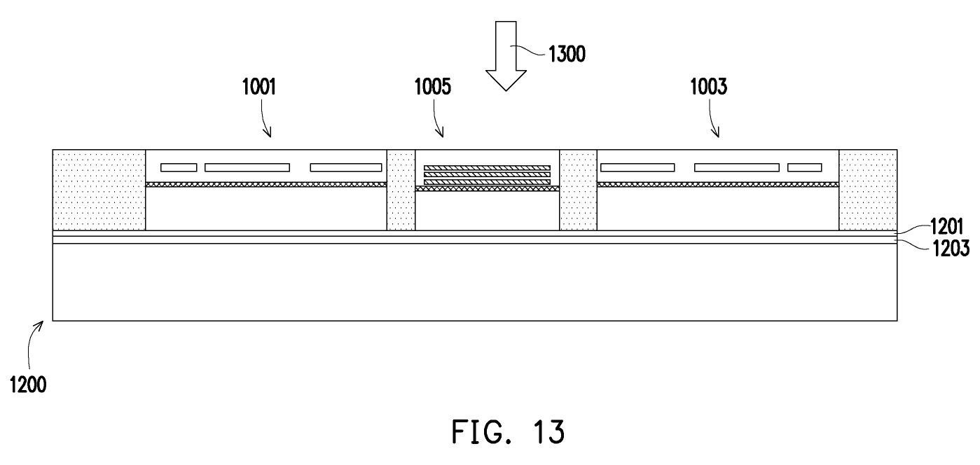

With reference now to FIG. 13, the intermediate device illustrated in FIG. 12 is depicted as flipped over and a first carrier removal process 1300 of the second carrier substrate 1000 is illustrated. In an embodiment, the first carrier removal process 1300 may be mechanical process, such as a grinding process, a chemical process, such as an etch, or a chemical mechanical polish (CMP) process, or the like. However, any suitable removal process may be utilized. In an embodiment, the first carrier removal process 1300 exposes the front side of the third semiconductor die 1001, the front side of the fourth semiconductor die 1003, and the front side of the second local interconnect die 1005.

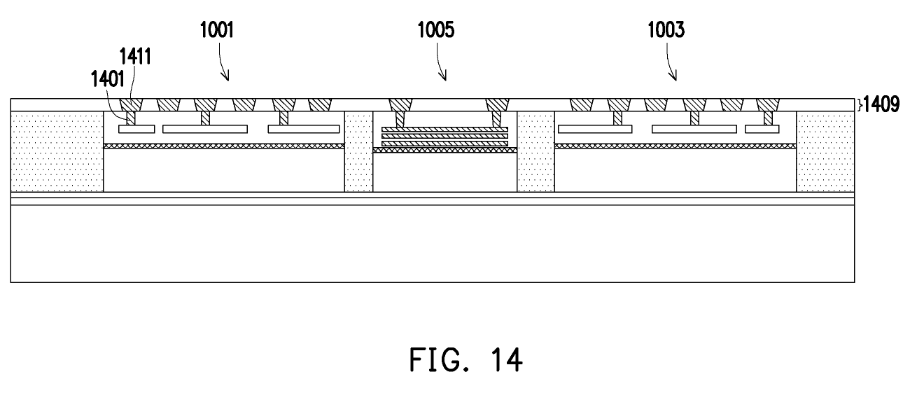

With reference now to FIG. 14, third metallization layer vias 1401 may be formed in the third semiconductor die 1001, the fourth semiconductor die 1003, and the second local interconnect die 1005. Further FIG. 14 illustrates a third wafer bond layer 1409 with third conductive bond pads 1411 formed over the front side of the third semiconductor die 1001, the front side of the fourth semiconductor die 1003, and the front side of the second local interconnect die 1005.

In an embodiment, the third metallization layer vias 1401 may be formed in a similar manner and from similar materials as described above with respect to the first metallization layer vias 201. The third metallization layer vias 1401 may be formed in physical and electrical contact with the first conductive structures 155 of first metallization layers 105.

In an embodiment, the third wafer bond layer 1409 may be formed in a similar manner and from similar materials as described above with respect to the first wafer bond layer 209. However any suitable process and materials may be utilized to form the third metallization layer vias 1401 and the third wafer bond layer 1409.

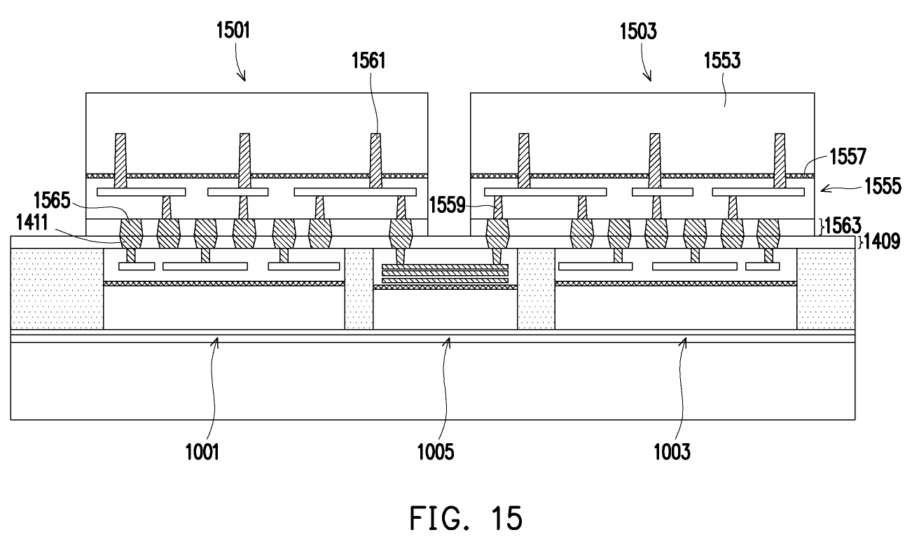

With reference now to FIG. 15, a first semiconductor device 1501 and a second semiconductor device 1503 are attached to the third wafer bond layer 1409. In an embodiment, the first semiconductor device 1501 and the second semiconductor device 1503 may each be a system on chip device, such as a logic device. However, any suitable functionality, such as logic dies, central processing unit (CPU) dies, input/output dies, combinations of these, or the like, may be utilized.

In an embodiment, the first semiconductor device 1501 and the second semiconductor device 1503 may each may comprise a first device substrate 1553, fourth active devices 1557, first device metallization layers 1555, first device metallization layer vias 1559, first device through substrate vias 1561, first device bond layers 1563, and first device conductive bond material 1565. In an embodiment, the first device substrate 1553 may be formed from similar materials as the first substrate 103. The fourth active devices 1557 may be formed in a similar manner as the first active devices 107. The first device metallization layers 1555 may be formed in a similar manner and from similar materials as the first metallization layers 105. The first device metallization layer vias 1559 may be formed in a similar manner and from similar materials as the first metallization layer vias 201. The first device through substrate vias 1561 may be formed in a similar manner and from similar materials as the first TSVs 111. The first device bond layers 1563 may be formed from similar materials and made from similar processes as the first wafer bond layer 209 and the first device conductive bond material 1565 may be formed from similar materials and may be formed from similar processes as the first conductive bond pads 207. However, any suitable materials and processes may be utilized in the formation of the structures of the first semiconductor device 1501 and the second semiconductor device 1503.

In an embodiment, the first semiconductor device 1501 and the second semiconductor device may be formed as part of a wafer, similar to the formation of the semiconductor wafer 100 described in FIG. 1. The first semiconductor device 1501 and the second semiconductor device 1503 may then be formed by singulating along scribe lines (not separately illustrated) as defined by seal rings (not separately illustrated) such as those depicted in FIG. 1 into individual semiconductor devices.

In an embodiment, a front side of the first semiconductor device 1501 and a front side of the second semiconductor device 1503 may be attached to the front side of the third semiconductor die 1001, the front side of the fourth semiconductor die 1003, and the front side of the second local interconnect die 1005. In an embodiment, the first semiconductor device 1501 and the second semiconductor device 1503 may be attached to the third wafer bond layer 1409 through either a bonding process or through an adhesive layer (not separately illustrated).

In an embodiment, the first semiconductor device 1501 may be attached to the third semiconductor die 1001 and the second local interconnect die 1005 by bonding the first device bond layers 1563 and the first device conductive bond material 1565 of the first semiconductor device 1501 to the third wafer bond layer 1409 and the third conductive bond pads 1411, respectively. In an embodiment, the first device bond layers 1563 and the first device conductive bond material 1565 may be bonded to the third wafer bond layer 1409 and the third conductive bond pads 1411 in a similar manner as discussed above with respect to the bonding of the first wafer bond layer 209 and the first conductive bond pads 207 to the second wafer bond layer 321 and the second conductive bond pads 323, respectively. However, any suitable bonding processes may be utilized to bond the first semiconductor device 1501 to the third wafer bond layer 1409.

In an embodiment, the second semiconductor device 1503 may be attached to the fourth semiconductor die 1003 and the second local interconnect die 1005 by bonding the first device bond layers 1563 and the first device conductive bond material 1565 of the second semiconductor device 1503 to the third wafer bond layer 1409 and the third conductive bond pads 1411, respectively. In an embodiment, the first device bond layers 1563 and the first device conductive bond material 1565 may be bonded to the third wafer bond layer 1409 and the third conductive bond pads 1411 in a similar manner as discussed above with respect to the bonding of the first wafer bond layer 209 and the first conductive bond pads 207 to the second wafer bond layer 321 and the second conductive bond pads 323, respectively. However, any suitable bonding process may be utilized to bond the second semiconductor device 1503 to the third wafer bond layer 1409.

In an embodiment, the second local interconnect die 1005 electrically couples the first semiconductor device 1501 to the second semiconductor device 1503. Further, in an embodiment, the third semiconductor die 1001 is electrically coupled to the first semiconductor device 1501 and the fourth semiconductor die 1003 is electrically coupled to the second semiconductor device 1503. In an embodiment, the third semiconductor die 1001 may be electrically coupled to the fourth semiconductor die 1003 through electrical coupling made by the second local interconnect die 1005 between the first semiconductor device 1501 that the third semiconductor die 1001 is electrically coupled to and the second semiconductor device 1503 that the fourth semiconductor die 1003 is electrically coupled to.

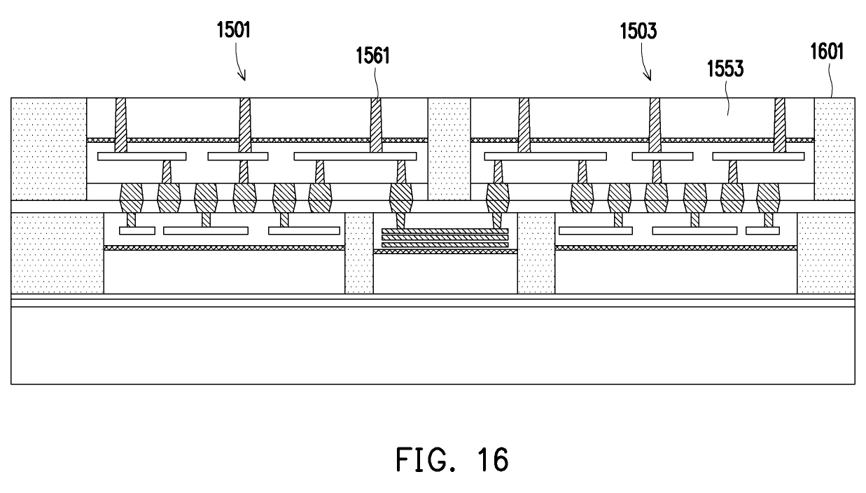

With reference now to FIG. 16, the first semiconductor device 1501 and the second semiconductor device 1503 may be encapsulated with a third encapsulant 1601. In an embodiment, the third encapsulant may be formed of and be formed by a similar process as the second encapsulant 1101 discussed above. However, any suitable process and material may be utilized for the third encapsulant 1601.

Further, following the encapsulation of the first semiconductor device 1501 and the second semiconductor device 1503 by the third encapsulant 1601 a thinning of the third encapsulant 1601, a backside of the first semiconductor device 1501, and a backside of the second semiconductor device 1503 may be performed such that top surfaces of the first device through substrate vias 1561 of the first semiconductor device 1501 and top surfaces of the first device through substrate vias 1561 of the second semiconductor device 1503 are exposed. The thinning may be performed, e.g., using a mechanical grinding, chemical approaches, or chemical mechanical polishing (CMP) process whereby chemical etchants and abrasives are utilized to react and grind away the third encapsulant 1601, and portions of the first device substrate 1553 of both the first semiconductor device 1501 and the second semiconductor device 1503 are removed. As such, the backside of the first semiconductor device 1501, the backside of the second semiconductor device 1503, and the third encapsulant 1601 may have a planar surface.

Furthermore, while the CMP process described above is presented as one illustrative embodiment, it is not intended to be limiting to the embodiments. Any other suitable removal process may be used to thin the third encapsulant 1601 and the first device substrate 1553. For example, a series of chemical etches may be utilized. This process and any other suitable process may be utilized to planarize the third encapsulant 1601 and the first device substrate 1553, and all such processes are fully intended to be included within the scope of the embodiments.

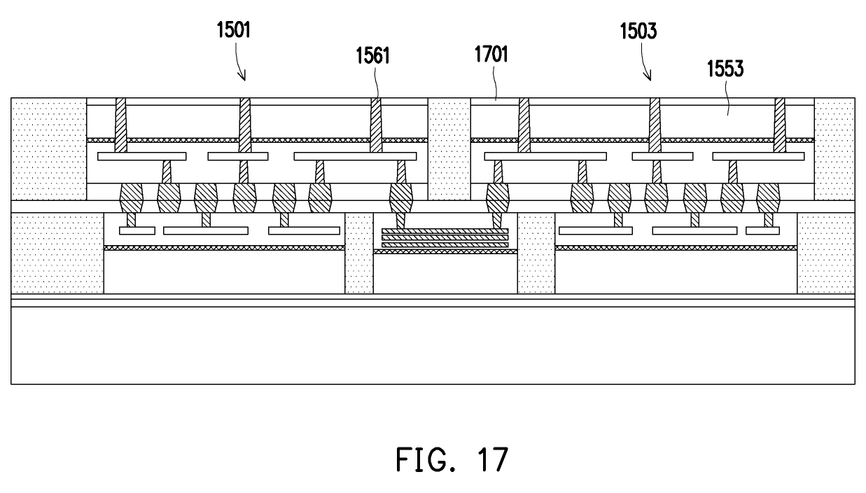

With reference now to FIG. 17, a formation of a second passivation film 1701 over a backside of the first semiconductor device 1501 and over a backside of the second semiconductor device 1503 is depicted. In an embodiment, an etch back process is performed on the first device substrate 1553 of each of the first semiconductor device 1501 and the first device substrate 1553 of the second semiconductor device 1503. The etch back process may be a time-controlled anisotropic plasma etch process that creates recesses (not separately illustrated) within the first device substrate 1553 of the both the first semiconductor device 1501 and within the first device substrate 1553 of the second semiconductor device 1503 such that the first device through substrate vias 1561 protrude from the first device substrate 1553. In an embodiment, the recesses may be formed to a sufficient depth as to facilitate the thickness of the second passivation film 1701.

In an embodiment, the second passivation film 1701 may comprise silicon oxide, silicon oxynitride, silicon nitride, or the like. In an embodiment, the second passivation film 1701 may be deposited by CVD, ALD, PVD, or the like. Following the deposition of the second passivation film 1701 a planarization process may be performed to expose a top surface of the first device through substrate vias 1561.

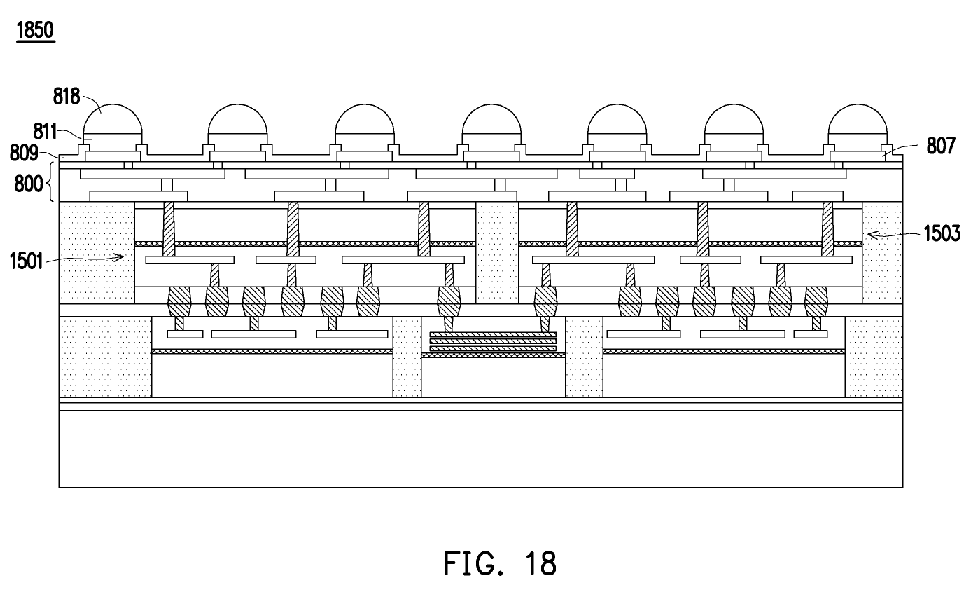

With reference now to FIG. 18, a formation of the first backside redistribution structure 800 is performed over the backside of the first semiconductor device 1501 and over the backside of the second semiconductor device 1503. In an embodiment, the first backside redistribution structure 800 is formed in a similar manner and from similar materials as discussed above but is formed over the first semiconductor device 1501 and the second semiconductor device 1503. Further, in an embodiment, the first metallization contact pad 807, the first redistribution passivation layer 809, the first UBMs 811, and the first conductive connectors 813 are formed over the first backside redistribution structure 800 in a similar manner and from similar materials as discussed above. The resulting structure depicted in FIG. 18 may be referred to as a second semiconductor package 1850.

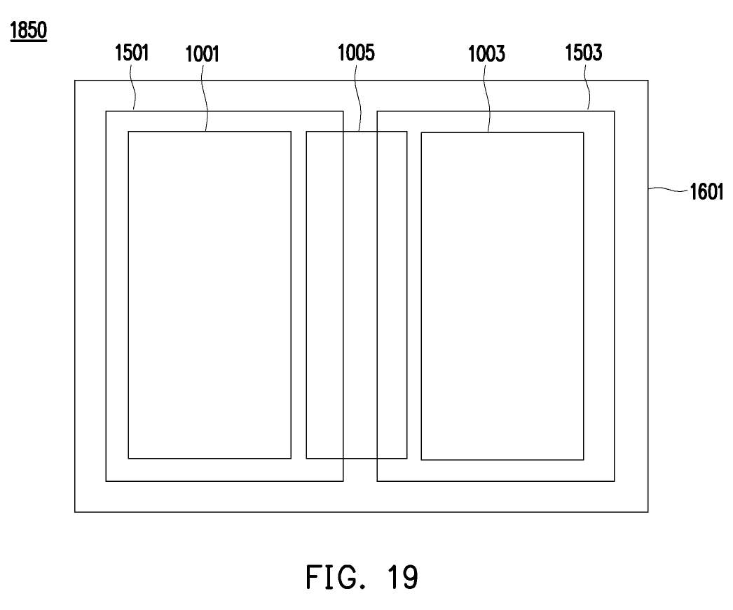

With reference now to FIG. 19, a top down cross section view of the second semiconductor package 1850 is depicted. In an embodiment, the third encapsulant 1601 in the top down cross section view defines the periphery of the second semiconductor package 1850. In an embodiment, the first semiconductor device 1501 completely covers the third semiconductor die 1001 and covers a first portion of the second local interconnect die 1005. In an embodiment, the second semiconductor device 1503 completely covers the fourth semiconductor die 1003 and covers a second portion of the second local interconnect die 1005.

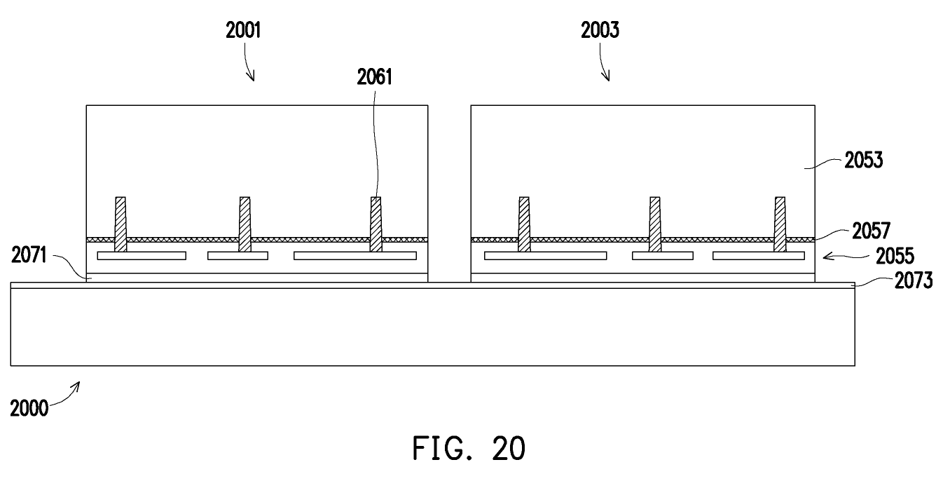

FIGS. 10 through 19 illustrate one specific package configuration, but other configurations are possible. For example, FIGS. 20 through 31 illustrate various intermediate steps of manufacturing a semiconductor package in accordance with some other embodiments. With reference now to FIG. 20, a third semiconductor device 2001 and a fourth semiconductor device 2003 are attached to a fourth carrier substrate 2000. In an embodiment, the third semiconductor device 2001 and the fourth semiconductor device 2003 may each be a system on chip device, such as a logic device. However, any suitable functionality, such as logic dies, central processing unit (CPU) dies, input/output dies, combinations of these, or the like, may be utilized.

In an embodiment, the third semiconductor device 2001 and the fourth semiconductor device 2003 may each may comprise a second device substrate 2053, fourth active devices 2057, second device metallization layers 2055, and second device through substrate vias 2061. In an embodiment, the second device substrate 2053 may be formed from similar materials as the first substrate 103. The fourth active devices 2057 may be formed in a similar manner as the first active devices 107. The second device metallization layers 2055 may be formed in a similar manner and from similar materials as the first metallization layers 105. The second device through substrate vias 2061 may be formed in a similar manner and from similar materials as the first TSVs 111. However, any suitable materials and processes may be utilized in the formation of the structures of the third semiconductor device 2001 and the fourth semiconductor device 2003.

In an embodiment, the third semiconductor device 2001 and the fourth semiconductor device 2003 may be formed as part of a wafer, similar to the formation of the semiconductor wafer 100 described in FIG. 1. The third semiconductor device 2001 and the fourth semiconductor device 2003 may then be formed by singulating along scribe lines (not separately illustrated) as defined by seal rings (not separately illustrated) such as those depicted in FIG. 1 into individual semiconductor devices.

In an embodiment, the fourth carrier substrate 2000 comprises, for example, silicon-based materials, such as silicon, glass, or the like. In an embodiment, the fourth carrier substrate 2000 is planar in order to accommodate the attachment of the third semiconductor device 2001 and the fourth semiconductor device 2003, which may be attached through a bonding process or through the use of an adhesive layer (not separately illustrated).

In an embodiment, the fourth carrier substrate 2000 is bonded to a front side of the third semiconductor device 2001 and a front side of the fourth semiconductor device 2003. In this embodiment, a sixth bonding layer 2071 may be formed over the second device metallization layers 2055 of the third semiconductor device 2001 and over the second device metallization layers 2055 the fourth semiconductor device 2003. In an embodiment, the sixth bonding layer 2071 may comprise an oxide, such as silicon oxide, silicon oxynitride, the like, or a combination thereof, and may be formed by high density plasma chemical vapor deposition (HDP-CVD), a flowable CVD (FCVD) (e.g., a CVD-based material deposition in a remote plasma system and post curing to make it convert to the oxide), ALD, physical vapor deposition (PVD), the like, or a combination thereof. Other oxide materials formed by any acceptable process may be used to form the sixth bonding layer 2071.

The fourth carrier substrate 2000 may be bonded to the sixth bonding layer 2071 of the third semiconductor device 2001 and the sixth bonding layer 2071 of the fourth semiconductor device 2003 by a seventh bonding layer 2073 of the fourth carrier substrate 2000. In an embodiment, the seventh bonding layer 2073 is formed over the fourth carrier substrate 2000 in a similar manner and from similar materials as the fourth bonding layer 1201. In accordance with some embodiments, the fourth carrier substrate 2000 comprises silicon, or the like. In an embodiment, the seventh bonding layer 2073 is bonded to the sixth bonding layer 2071 through a dielectric-to-dielectric bonding process (e.g., oxide-to-oxide bonding) forming a dielectric-to dielectric bond (e.g., an oxide-to-oxide bond). The dielectric-to-dielectric bonding process may be carried out in a similar manner as discussed above.

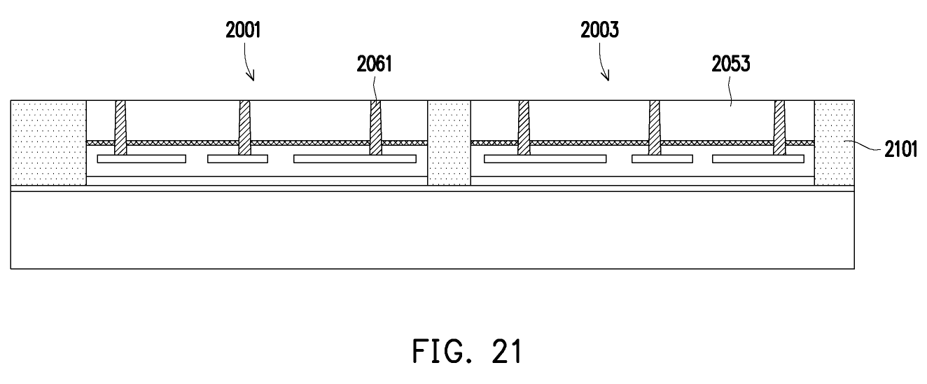

With reference now to FIG. 21, the third semiconductor device 2001 and the fourth semiconductor device 2003 may be encapsulated with a fourth encapsulant 2101. In an embodiment, the fourth encapsulant 2101 may be formed of and be formed by a similar process as the third encapsulant 1601 discussed above. However, any suitable process and material may be utilized for the fourth encapsulant 2101.

Further, following the encapsulation of the third semiconductor device 2001 and the fourth semiconductor device 2003 by the fourth encapsulant 2101 a thinning of the fourth encapsulant 2101, a backside of the third semiconductor device 2001, and a backside of the fourth semiconductor device 2003 may be performed such that top surfaces of the second device through substrate vias 2061 of the third semiconductor device 2001 and top surfaces of the second device through substrate vias 2061 of the fourth semiconductor device 2003 are exposed. The thinning may be performed, e.g., using a mechanical grinding, chemical approaches, or chemical mechanical polishing (CMP) process whereby chemical etchants and abrasives are utilized to react and grind away the fourth encapsulant 2101, and portions of the second device substrate 2053 of both the third semiconductor device 2001 and the fourth semiconductor device 2003 are removed. As such, the backside of the third semiconductor device 2001, the backside of the fourth semiconductor device 2003, and the fourth encapsulant 2101 may have a planar surface.

Furthermore, while the CMP process described above is presented as one illustrative embodiment, it is not intended to be limiting to the embodiments. Any other suitable removal process may be used to thin the fourth encapsulant 2101 and the second device substrate 2053. For example, a series of chemical etches may be utilized. This process and any other suitable process may be utilized to planarize the fourth encapsulant 2101 and the second device substrate 2053, and all such processes are fully intended to be included within the scope of the embodiments.

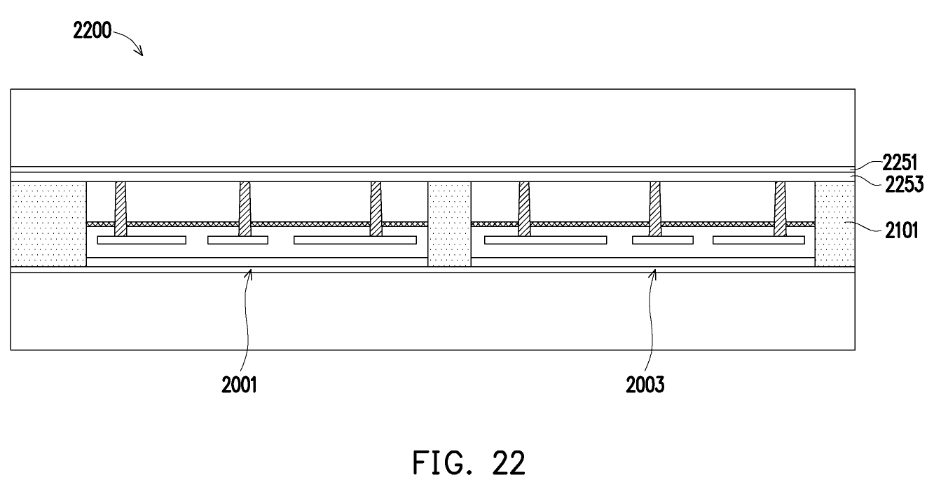

With reference now to FIG. 22, a fifth carrier substrate 2200 is attached to the backside of the third semiconductor device 2001 and to the backside of the fourth semiconductor device 2003. In an embodiment, the backside of the third semiconductor device 2001 and the backside of the fourth semiconductor device 2003 are bonded to the fifth carrier substrate 2200. In this embodiment, an eighth bonding layer 2251 may be formed over the fifth carrier substrate 2200. In an embodiment, the fifth carrier substrate 2200 comprises, for example, silicon-based materials, such as silicon, glass, or the like. In an embodiment, the eighth bonding layer 2251 may comprise an oxide, such as silicon oxide, silicon oxynitride, the like, or a combination thereof and may be formed by high density plasma chemical vapor deposition (HDP-CVD), a flowable CVD (FCVD) (e.g., a CVD-based material deposition in a remote plasma system and post curing to make it convert to the oxide), ALD, physical vapor deposition (PVD), the like, or a combination thereof. Other oxide materials formed by any acceptable process may be used to form the eighth bonding layer 2251. Further, a ninth bonding layer 2253 may be formed over the planar surface of the third semiconductor device 2001, the fourth semiconductor device 2003, and the fourth encapsulant 2101. In an embodiment, the ninth bonding layer 2253 may comprise an oxide, such as silicon oxide, silicon oxynitride, the like, or a combination thereof, and may be formed by high density plasma chemical vapor deposition (HDP-CVD), a flowable CVD (FCVD) (e.g., a CVD-based material deposition in a remote plasma system and post curing to make it convert to the oxide), ALD, physical vapor deposition (PVD), the like, or a combination thereof. Other oxide materials formed by any acceptable process may be used to form the ninth bonding layer 2253.

In an embodiment, the eighth bonding layer 2251 is bonded to the ninth bonding layer 2253 through a dielectric-to-dielectric bonding process (e.g., oxide-to-oxide bonding) forming a dielectric-to dielectric bond (e.g., an oxide-to-oxide bond). The dielectric-to-dielectric bonding process may be carried out in a similar manner as discussed above.

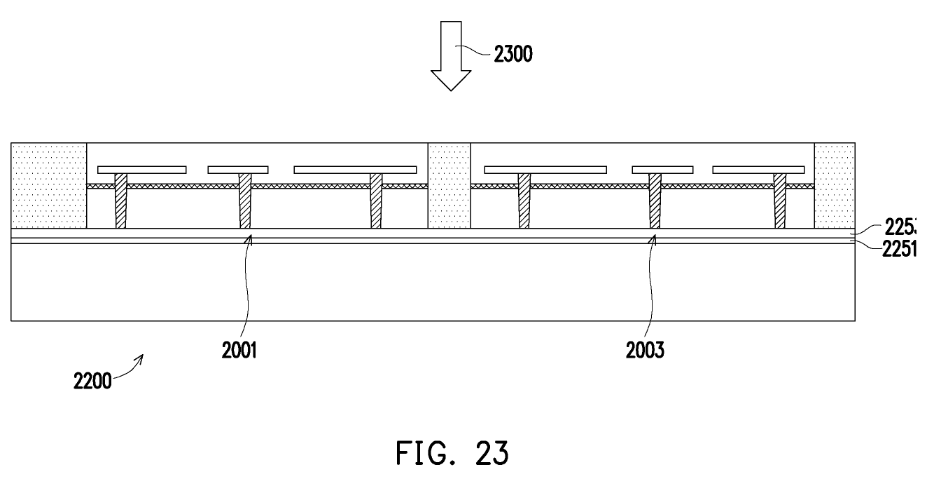

With reference now to FIG. 23, the intermediate device illustrated in FIG. 22 is flipped over and a second carrier removal process 2300 of the fourth carrier substrate 2000 is performed. In an embodiment, the second carrier removal process 2300 may be mechanical process, such as a grinding process, a chemical process, such as an etch, or a chemical mechanical polish (CMP) process, or the like. However, any suitable removal process may be utilized. In an embodiment, the second carrier removal process 2300 exposes the front side of the third semiconductor device 2001 and the front side of the fourth semiconductor device 2003.

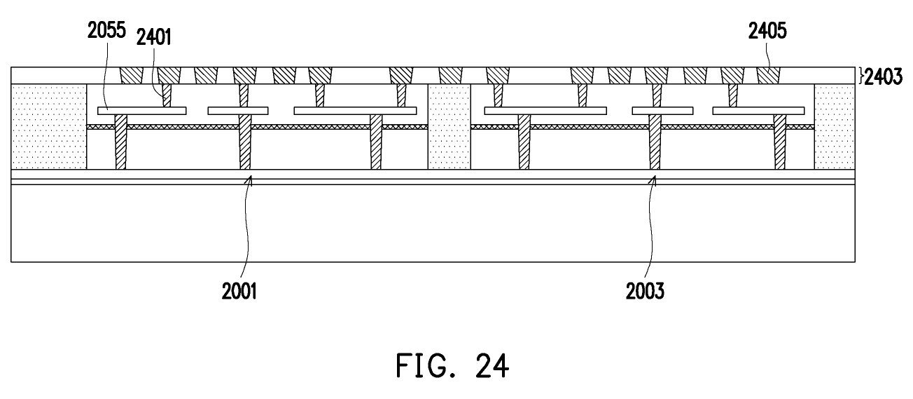

With reference now to FIG. 24, second device metallization layer vias 2401 may be formed in the third semiconductor device 2001 and the fourth semiconductor device 2003. Further FIG. 24 illustrates a fourth wafer bond layer 2403 with fourth conductive bond pads 2405 formed over the front side of the third semiconductor device 2001 and the front side of the fourth semiconductor device 2003.

In an embodiment, the second device metallization layer vias 2401 may be formed in a similar manner and from similar materials as described above with respect to the first metallization layer vias 201. The second device metallization layer vias 2401 may be formed in physical and electrical contact with second device metallization layers 2055.

In an embodiment, the fourth wafer bond layer 2403 may be formed in a similar manner and from similar materials as described above with respect to the first wafer bond layer 209 and the fourth conductive bond pads 2405 may be formed in similar manner and from similar materials as described above with respect to the first conductive bond pads 207. However any suitable process and materials may be utilized to form the second device metallization layer vias 2401, the fourth wafer bond layer 2403, and the fourth conductive bond pads 2405.

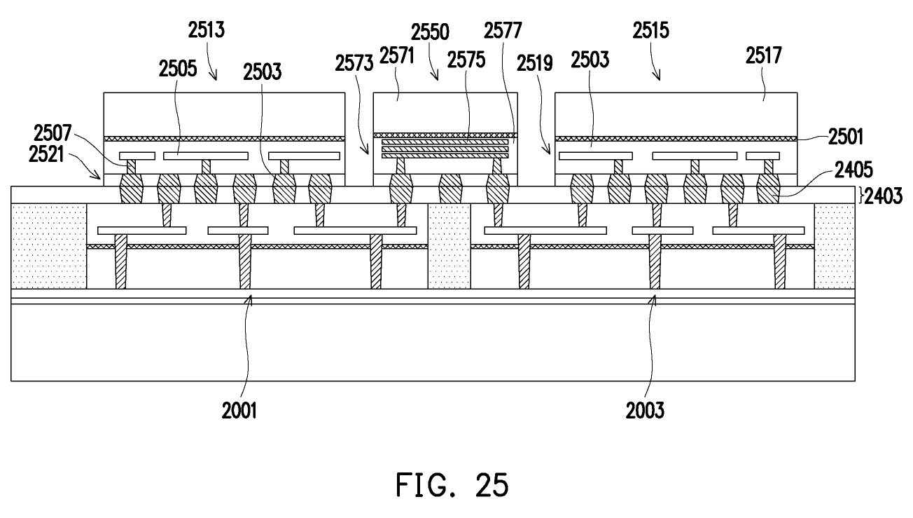

With reference now to FIG. 25, a fifth semiconductor die 2513, a sixth semiconductor die 2515, and a third local interconnect die 2550 (sometimes referred to as a local silicon interconnect (LSI) or as a silicon bridge) are bonded to the fourth conductive bond pads 2405 and the fourth wafer bond layer 2403. In an embodiment each of the fifth semiconductor die 2513 and the sixth semiconductor die 2515 may each be a system on chip device, such as a logic device. However, any suitable functionality, such as logic dies, central processing unit (CPU) dies, input/output dies, combinations of these, or the like, may be utilized.

In an embodiment the fifth semiconductor die 2513 and the sixth semiconductor die 2515 may each have fourth substrates 2517, fifth active devices 2501, fourth metallization layers 2519, fourth metallization layer vias 2507, fifth wafer bond layers 2521, and fifth conductive bond pads 2523. In an embodiment, the fourth metallization layers 2519 comprises fourth alternating layers of dielectric 2503 and fourth conductive structures 2505. In an embodiment the fourth substrates 2517, the fifth active devices 2501, the fourth metallization layers 2519, the fourth metallization layer vias 2507, the fifth wafer bond layers 2521, and the fifth conductive bond pads 2523 may be formed similar to the first substrate 103, the first active devices 107, the first metallization layers 105, the first metallization layer vias 201, the first wafer bond layer 209, and the first conductive bond pads 207, respectively, as discussed above. However, in other embodiments these structures may be formed using different processes and different materials.

Further, in an embodiment, the third local interconnect die 2550 comprises a third interconnect substrate 2571 that supports a third interconnect structure 2573, which comprises third interconnect metallization patterns 2575 (e.g., conductive lines, vias, and conductive pads) in one or more third interconnect dielectric layers 2557. The third interconnect metallization patterns 2575 and the third interconnect dielectric layers 2577 may be formed in a similar manner and form similar materials as discussed with respect to the first conductive structures 155 of the first metallization layers 105 and the first alternating layers of dielectric material 153 of the first metallization layers 105. In an embodiment, the third interconnect substrate 2571 may be formed of silicon, such as bulk silicon. In an embodiment, the third interconnect substrate 2571 may be formed in a similar manner and from similar materials as the first substrate 103.

In an embodiment, the fifth semiconductor die 2513 is bonded over the third semiconductor device 2001. The fifth semiconductor die 2513 may be bonded over the third semiconductor device 2001 by bonding the fifth wafer bond layers 2521 and the fifth conductive bond pads 2523 of the fifth semiconductor die 2513 to the fourth wafer bond layer 2403 and the fourth conductive bond pads 2405 over the front side of the third semiconductor device 2001, respectively. In an embodiment, the bonding the fifth wafer bond layers 2521 and the fifth conductive bond pads 2523 of the fifth semiconductor die 2513 to the fourth wafer bond layer 2403 and the fourth conductive bond pads 2405 may be performed in a similar manner as discussed above with respect to the bonding of the first wafer bond layer 209 and the first conductive bond pads 207 to the second wafer bond layer 321 and the second conductive bond pads 323, respectively. However, any suitable bonding process may be utilized to bond the fifth semiconductor die 2513 to the fourth wafer bond layer 2403.

In an embodiment, the sixth semiconductor die 2515 is bonded over the fourth semiconductor device 2003. The sixth semiconductor die 2515 may be bonded over the fourth semiconductor device 2003 by bonding the fifth wafer bond layers 2521 and the fifth conductive bond pads 2523 of the sixth semiconductor die 2515 to the fourth wafer bond layer 2403 and the fourth conductive bond pads 2405 over the front side of the fourth semiconductor device 2003, respectively. In an embodiment, the bonding the fifth wafer bond layers 2521 and the fifth conductive bond pads 2523 of the sixth semiconductor die 2515 to the fourth wafer bond layer 2403 and the fourth conductive bond pads 2405 may be performed in a similar manner as discussed above with respect to the bonding of the first wafer bond layer 209 and the first conductive bond pads 207 to the second wafer bond layer 321 and the second conductive bond pads 323, respectively. However, any suitable bonding process may be utilized to bond the sixth semiconductor die 2515 to the fourth wafer bond layer 2403.

Further, in an embodiment, conductive pads of the third interconnect metallization patterns 2575 along with one of the third interconnect dielectric layers 2577 may be used to bond the third local interconnect die 2550 to the fourth wafer bond layer 2403 and the fourth conductive bond pads 2405 in a similar manner as discussed above with respect to the bonding of the second wafer bond layers 321 and the second conductive bond pads 323 to the first wafer bond layer 209 and the first conductive bond pads 207, respectively.

In an embodiment, the third local interconnect die 2550 electrically couples the third semiconductor device 2001 to the fourth semiconductor device 2003. Further, in an embodiment, the fifth semiconductor die 2513 is electrically coupled to the third semiconductor device 2001 and the sixth semiconductor die 2515 is electrically coupled to the fourth semiconductor device 2003. In an embodiment, the fifth semiconductor die 2513 may be electrically coupled to the sixth semiconductor die 2515 through electrical coupling made by the third local interconnect die 2550 between the third semiconductor device 2001 that the fifth semiconductor die 2513 is electrically coupled to and the fourth semiconductor device 2003 that the sixth semiconductor die 2515 is electrically coupled to.

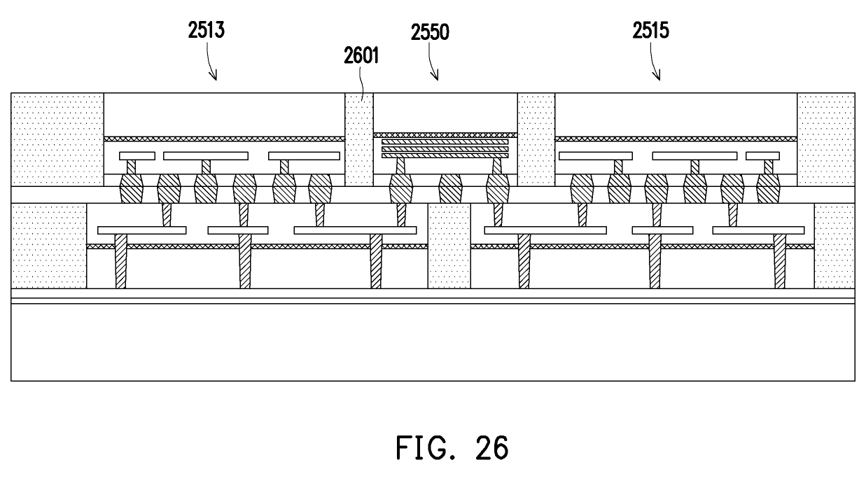

With reference now to FIG. 26, the fifth semiconductor die 2513, the sixth semiconductor die 2515, and the third local interconnect die 2550 may be encapsulated with a fifth encapsulant 2601. In an embodiment, the fifth encapsulant 2601 may be formed of and be formed by a similar process as the third encapsulant 1601 discussed above. However, any suitable process and material may be utilized for the fifth encapsulant 2601.

Further, following the encapsulation of the fifth semiconductor die 2513, the sixth semiconductor die 2515, and the third local interconnect die 2550 by the fifth encapsulant 2601 a thinning of the fifth encapsulant 2601 may be performed. In an embodiment, the thinning of the fifth encapsulant 2601 exposes a backside of the fifth semiconductor die 2513, a backside of the sixth semiconductor die 2515, and a backside of the third local interconnect die 2550 for further processing. The thinning may be performed, e.g., using a mechanical grinding, chemical approaches, or chemical mechanical polishing (CMP) process whereby chemical etchants and abrasives are utilized to react and grind away the fifth encapsulant 2601 so that the fifth semiconductor die 2513, the sixth semiconductor die 2515, and the third local interconnect die 2550 may have a planar surface that is also coplanar with the fifth encapsulant 2601.

Furthermore, while the CMP process described above is presented as one illustrative embodiment, it is not intended to be limiting to the embodiments. Any other suitable removal process may be used to thin the fifth encapsulant 2601. For example, a series of chemical etches may be utilized. This process and any other suitable process may be utilized to planarize the fifth encapsulant 2601, and all such processes are fully intended to be included within the scope of the embodiments.

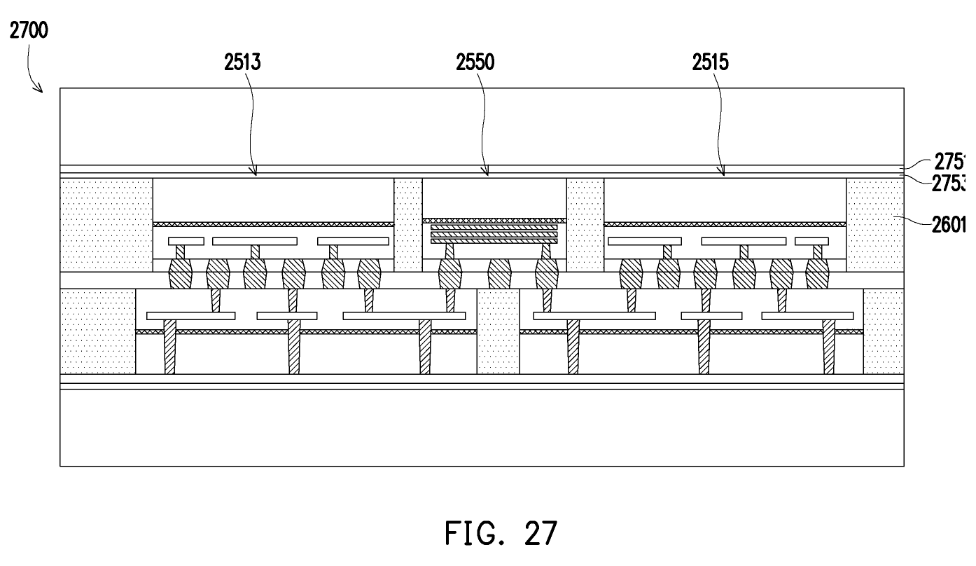

With reference now to FIG. 27, a sixth carrier substrate 2700 is attached to the backside of the fifth semiconductor die 2513, the backside of the sixth semiconductor die 2515, the backside of the third local interconnect die 2550, and the fifth encapsulant 2601. In an embodiment, the backside of the fifth semiconductor die 2513, the backside of the sixth semiconductor die 2515, the backside of the third local interconnect die 2550, and the fifth encapsulant 2601 are bonded to the sixth carrier substrate 2700. In this embodiment, a tenth bonding layer 2751 may be formed over the sixth carrier substrate 2700. In an embodiment, the tenth bonding layer 2751 may comprise an oxide, such as silicon oxide, silicon oxynitride, the like, or a combination thereof and may be formed by high density plasma chemical vapor deposition (HDP-CVD), a flowable CVD (FCVD) (e.g., a CVD-based material deposition in a remote plasma system and post curing to make it convert to the oxide), ALD, physical vapor deposition (PVD), the like, or a combination thereof. Other oxide materials formed by any acceptable process may be used to form the tenth bonding layer 2751. Further, an eleventh bonding layer 2753 may be formed over the planar surface of the fifth semiconductor die 2513, the sixth semiconductor die 2515, the third local interconnect die 2550, and the fifth encapsulant 2601. In an embodiment, the eleventh bonding layer 2753 may comprise an oxide, such as silicon oxide, silicon oxynitride, the like, or a combination thereof, and may be formed by high density plasma chemical vapor deposition (HDP-CVD), a flowable CVD (FCVD) (e.g., a CVD-based material deposition in a remote plasma system and post curing to make it convert to the oxide), ALD, physical vapor deposition (PVD), the like, or a combination thereof. Other oxide materials formed by any acceptable process may be used to form the eleventh bonding layer 2753.

In an embodiment, the tenth bonding layer 2751 is bonded to the eleventh bonding layer 2753 through a dielectric-to-dielectric bonding process (e.g., oxide-to-oxide bonding) forming a dielectric-to dielectric bond (e.g., an oxide-to-oxide bond). The dielectric-to-dielectric bonding process may be carried out in a similar manner as discussed above.

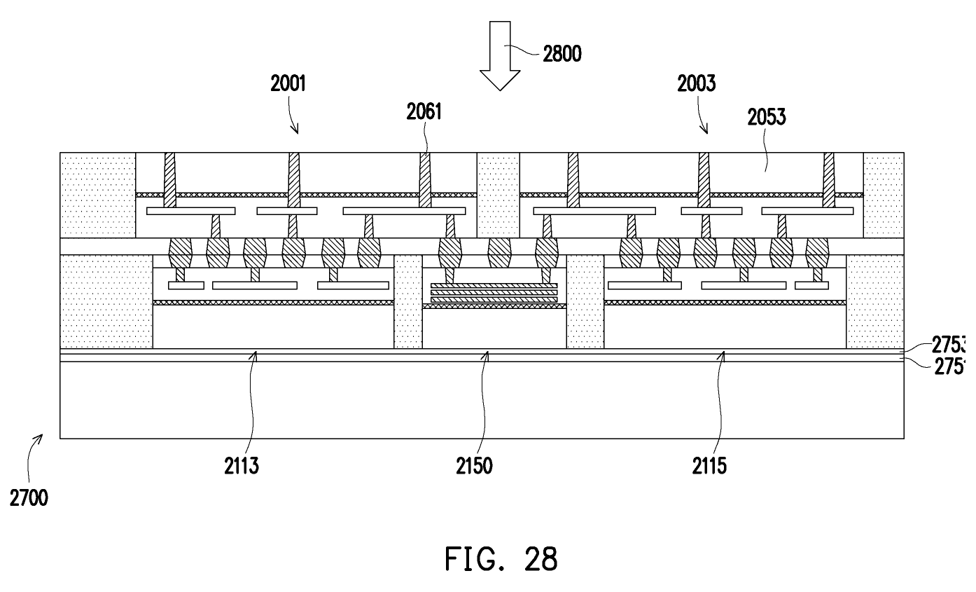

With reference now to FIG. 28, the intermediate device illustrated in FIG. 27 is flipped over and a third carrier removal process 2800 of the fifth carrier substrate 2200 is performed. In an embodiment, the third carrier removal process 2800 may be mechanical process, such as a grinding process, a chemical process, such as an etch, or a chemical mechanical polish (CMP) process, or the like. However, any suitable removal process may be utilized. In an embodiment, the third carrier removal process 2800 exposes the backside of the third semiconductor device 2001 and the backside of the fourth semiconductor device 2003.

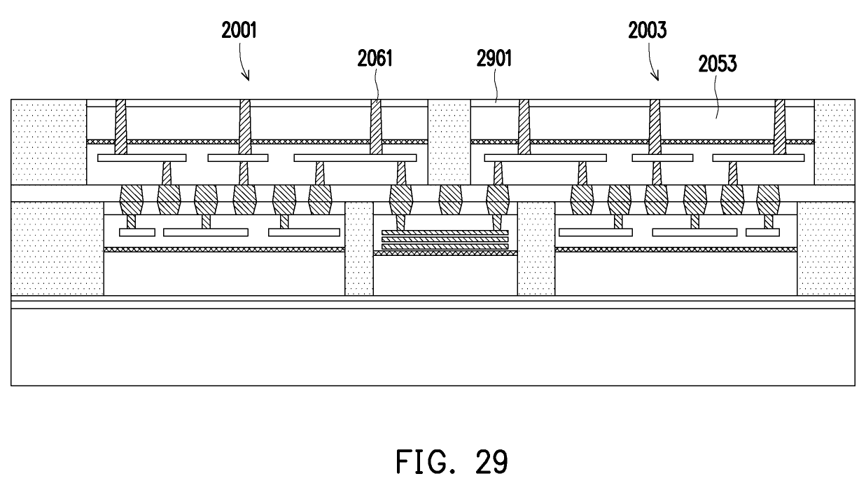

With reference now to FIG. 29, a formation of a third passivation film 2901 over a backside of the third semiconductor device 2001 and over a backside of the fourth semiconductor device 2003 is performed. In an embodiment, an etch back process is performed on the second device substrate 2053 of each of the third semiconductor device 2001 and the second device substrate 2053 of the fourth semiconductor device 2003. The etch back process may be a time-controlled anisotropic plasma etch process that creates recesses (not separately illustrated) within the second device substrate 2053 of the both the third semiconductor device 2001 and within the second device substrate 2053 of the fourth semiconductor device 2003 such that the second device through substrate vias 2061 protrude from the second device substrate 2053. In an embodiment, the recesses may be formed to a sufficient depth as to facilitate the thickness of the third passivation film 2901.

In an embodiment, the third passivation film 2901 may comprise silicon oxide, silicon oxynitride, silicon nitride, or the like. In an embodiment, the third passivation film 2901 may be deposited by CVD, ALD, PVD, or the like. Following the deposition of the third passivation film 2901 a planarization process may be performed to expose a top surface of the second device through substrate vias 2061.

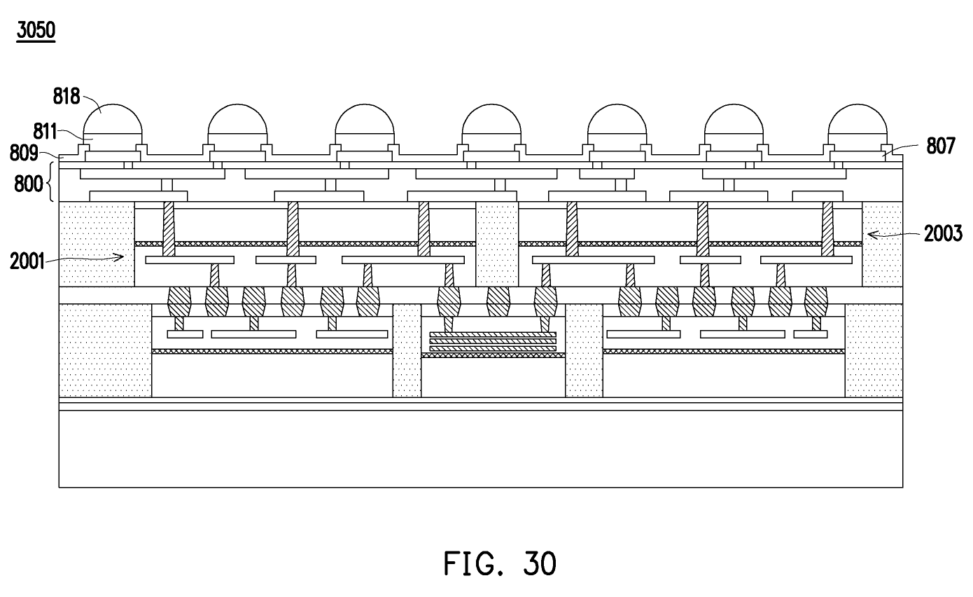

With reference now to FIG. 30, a formation of the first backside redistribution structure 800 is performed over the backside of the third semiconductor device 2001 and over the backside of the fourth semiconductor device 2003. In an embodiment, the first backside redistribution structure 800 is formed in a similar manner and from similar materials as discussed above but is formed over the third semiconductor device 2001 and the fourth semiconductor device 2003. Further, in an embodiment, the first metallization contact pad 807, the first redistribution passivation layer 809, the first UBMs 811, and the first conductive connectors 813 are formed over the first backside redistribution structure 800 in a similar manner and from similar materials as discussed above. The resulting structure depicted in FIG. 30 may be referred to as a third semiconductor package 3050.

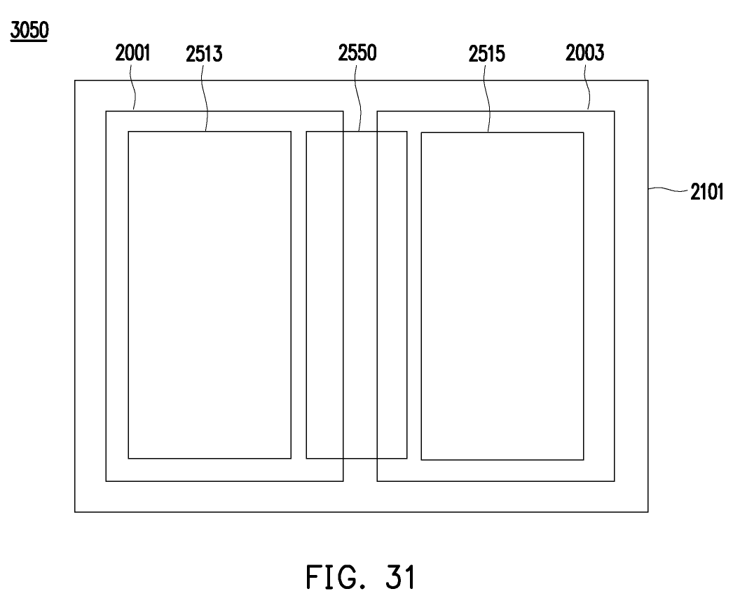

With reference now to FIG. 31, a top down cross section view of the third semiconductor package 3050 is depicted. In an embodiment, the fourth encapsulant 2101 in the top down cross section view defines the periphery of the third semiconductor package 3050. In an embodiment, the third semiconductor device 2001 completely covers the fifth semiconductor die 2513 and covers a first portion of the third local interconnect structure 2050. In an embodiment, the fourth semiconductor device 2003 completely covers the sixth semiconductor die 2515 and covers a second portion of the third local interconnect die 2550.

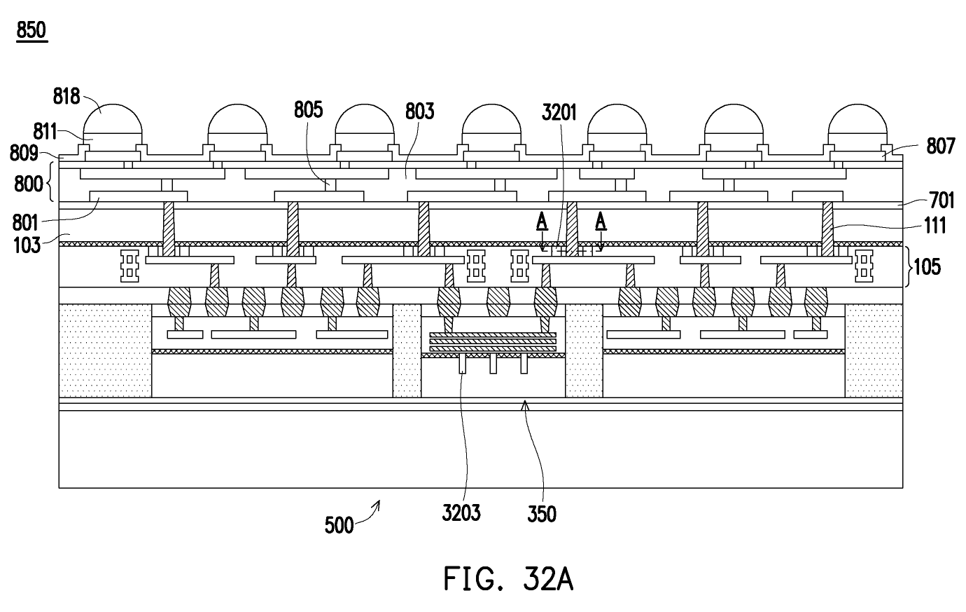

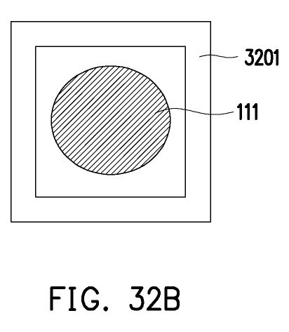

With reference now to FIG. 32A, the first semiconductor package 850 is depicted with TSV guard rings 3201 around the first TSVs 111 and deep trench capacitors (DTCs) 3203 may be optionally formed in the first local interconnect die 350. In an embodiment, the TSV guard rings 3201 may be formed by a metal damascene process. The TSV guard rings 3201 may be formed in the first metallization layers 105 and surround the first TSVs 111 in the first metallization layers 105 in a top down view (see e.g., FIG. 32B). In an embodiment, the TSV guard rings 3201 do not extend into the first substrate 103. The TSV guard rings 3201 may comprise of a metal such as copper. However, any suitable method and material may be utilized in forming the TSV guard rings 3201.

In an embodiment, the TSV guard rings 3201 may reduce a leakage current and provide electrical isolation between the first TSVs 111 and other structures in the first metallization layers 105. In addition, first TSVs 111 can introduce mechanical stress and the TSV guard rings 3201 can provide stress relief during fabrication and operation of the first semiconductor package 850.

FIG. 32A further depicts passive devices, such as deep trench capacitors (DTCs) 3203, formed in the first local interconnect die 350 of the first semiconductor 850. In some embodiments, the DTCs 3203 may be formed in the first interconnect substrate 351 of the first local interconnect die 350. In an embodiment, The DTCs 3203 may include a three-dimensional corrugated stack of metal layers (not separately illustrated) separated by insulating layers (not separately illustrated). In an embodiment, the DTCs 3203 may be a single-trench capacitor that includes the metal vias (not separately illustrated) in a single recess (not separately illustrated) or may be a multi-trench capacitor that includes the metal vias in multiple recesses.

Additionally, while FIG. 32A illustrates the TSV guard rings 3201 and the DTCs 3203 in the first semiconductor package 850 this is merely illustrative. The TSV guard rings 3201 may be formed from similar materials and in a similar process to surround the first device through substrate vias 1561 in the second semiconductor package 1850 and to surround the second device through substrate vias 2061 in the third semiconductor package 3050. Similarly, the DTCs may be formed in a similar process and from similar materials in the second local interconnect die 1005 of the second semiconductor package 1850 and in the third local interconnect die 2550 of the third semiconductor package 3050.

With reference now to FIG. 32B, a top down section view of TSV guard ring 3201 surrounding the first TSVs 111 taken at the section cut ‘A-A’ in FIG. 32A. In an embodiment, the TSV guard rings 3201 may be a rectangular shape (e.g., a square shape) in a top down view. However, any suitable shape may be utilized to surround the first TSVs 111.

Benefits may be achieved by utilizing various carrier substrates (e.g., the first carrier substrate 500, the second carrier substrate 1000, the third carrier substrate 1200, etc.) to bond various semiconductor devices or semiconductor wafers with active circuitry in a front side to front side orientation in conjunction with various local interconnect structures (e.g., the first local interconnect die 350, the second local interconnect die 1005, and the third local interconnect die 2550). The various carrier substrates allow for the various local interconnect structures to be formed at different stages of manufacturing allowing for increased flexibility. Further, the front side to front side orientation allows for a formation of a backside redistribution structure (e.g., the first backside redistribution structure 800) to facilitate external connections. The backside redistribution structure in combination with the various local interconnect structure allows for increased interconnectivity between functional circuitry within the various semiconductor packages (e.g., the first semiconductor package 850, the second semiconductor package 1850, and the third semiconductor package 3050) and improved functionality, efficiency and performance of these various semiconductor packages. The improved design flexibility allows for the improved functionality of manufacturing the various semiconductor packages at a reduced cost.

In accordance with an embodiment, a method includes bonding a first semiconductor die to a first side of a first semiconductor device, the first semiconductor device including a first region of active circuitry and a second region of active circuitry that is electrically isolated from the first region of active circuitry, bonding a second semiconductor die to the first side of the first semiconductor device adjacent to the first semiconductor die, bonding a local interconnect die to the first side of the first semiconductor device between the first semiconductor die and the second semiconductor die, wherein the local interconnect die electrically connects the first region of active circuitry to the second region of active circuitry, and forming a redistribution structure over a second of the first semiconductor device opposite the first side of the first semiconductor device, wherein the forming the redistribution structure includes forming a plurality of dielectric layers over a second side of the first semiconductor device, the second side opposite the first side, and forming a plurality of metallization layers within the plurality of dielectric layers. In an embodiment, the first region of active circuity and the second region of active circuitry are disposed on a same semiconductor substrate. In an embodiment, further including prior to the bonding the first semiconductor die to the first semiconductor device, forming a first seal ring and a second seal ring within the first semiconductor device, wherein the first seal ring surrounds the first region of active circuitry and the second seal ring surrounds the second region of active circuitry. In an embodiment, after the bonding the local interconnect die to the first semiconductor device, wherein the local interconnect die directly covers the first seal ring, the second seal ring and an intermediate region disposed in between the first seal ring and the second seal ring. In an embodiment, after the forming the first seal ring and the second seal ring in the first semiconductor device, a thinning process is performed on a backside of the first semiconductor device exposing through substrate vias of the first semiconductor device, the through substrate vias electrically coupled to an interconnect structure of the first semiconductor device. In an embodiment, the bonding the first semiconductor die to the first semiconductor device includes forming metal-to-metal bonds and dielectric-to-dielectric bonds between the first semiconductor device and the first semiconductor die. In an embodiment, further including bonding the local interconnect die to a carrier substrate before the bonding the local interconnect die to the first side

of the first semiconductor device. In an embodiment, further including bonding the local interconnect die to a carrier substrate after the bonding the local interconnect die to the first side of the first semiconductor device.

In accordance with an embodiment, a device includes a semiconductor device including a semiconductor substrate, first through substrate vias and second through substrate vias extending through the semiconductor substrate, an interconnect structure on the semiconductor substrate, the interconnect structure including first metallization patterns electrically coupled to the first through substrate vias and second metallization patterns electrically coupled to the second through substrate vias, a first seal ring surrounding the first metallization patterns to define a first semiconductor region, and a second seal ring surrounding the second metallization patterns to define a second semiconductor region, a local interconnect structure bonded to both the first semiconductor region and the second semiconductor region, wherein the local interconnect structure directly covers both the first seal ring and the second seal ring, and a first redistribution structure on the semiconductor device, the first redistribution structure being electrically connected to the first semiconductor region by the first through substrate vias and electrically connected to the second semiconductor region by the second through substrate vias. In an embodiment, further including a first semiconductor die bonded to the first semiconductor region, and a second semiconductor die bonded to the second semiconductor region. In an embodiment, the first semiconductor die is electrically coupled to the second semiconductor die through the first redistribution structure. In an embodiment, first semiconductor region is electrically coupled to the second semiconductor region through the local interconnect structure, the first semiconductor die is electrically coupled to the first semiconductor region, and the second semiconductor die is electrically coupled to the second semiconductor region. In an embodiment, the first semiconductor die and the second semiconductor die are embedded in a molding compound. In an embodiment, the first semiconductor region is electrically isolated from the second semiconductor region within the semiconductor device.

In accordance with an embodiment, a method includes bonding a first metallization structure of a first semiconductor die to a second metallization structure of a semiconductor device, wherein the second metallization structure is surrounded by a first seal ring, bonding a third metallization structure of a second semiconductor die to a fourth metallization structure of the semiconductor device, wherein the fourth metallization structure is surrounded by a second seal ring, bonding a fifth metallization structure of a local interconnect die to both the second metallization structure and the fourth metallization structure of the semiconductor device, wherein the fifth metallization structure overlaps both the first seal ring and the second seal ring, and forming a first redistribution structure on an opposing side of the semiconductor device as the first semiconductor die, the second semiconductor die, and the local interconnect die. In an embodiment, forming the first redistribution structure includes forming a sixth metallization structure in dielectric layers using one or more damascene processes. In an embodiment, further including forming a contact pad the sixth metallization structure, forming a passivation layer over the contact pad, forming an under bump metallization (UBM) in direct physical contact with the contact pad, a portion of the UBM embedded in the passivation layer, and forming a conductive connector in direct physical contact with the UBM opposite the contact pad. In an embodiment, between the first seal ring and the second seal ring is an intermediate region with no active circuitry. In an embodiment, further including after the bonding the first metallization structure of the first semiconductor die to second metallization structure of the semiconductor device, bonding a carrier substrate to a semiconductor substrate of the first semiconductor die opposite the first metallization structure. In an embodiment, surrounding the second metallization structure with the first seal ring electrically isolates the second metallization structure from the fourth metallization structure within the semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a semiconductor device comprising a first semiconductor region and a second semiconductor region laterally adjacent to the first semiconductor region;
a first semiconductor die electrically coupled to the first semiconductor region;
a second semiconductor die electrically coupled to the second semiconductor region; and
a local interconnect die electrically coupling the first semiconductor region to the second semiconductor region such that the first semiconductor die is electrically coupled to the second semiconductor die through the first semiconductor region, the local interconnect die, and the second semiconductor region.

2. The device of claim 1, wherein the semiconductor device comprises a first seal ring surrounding the first semiconductor region and a second seal ring surrounding the second semiconductor region.

3. The device of claim 2, wherein the semiconductor device further comprises an intermediate region between the first seal ring and the second seal ring, the intermediate region being free of active circuitry.

4. The device of claim 3, wherein the local interconnect die overlaps the first seal ring, overlaps the second seal ring, and overlaps the intermediate region in a top down view.

5. The device of claim 2, wherein the first seal ring completely encircles the first semiconductor die in a plan view and the second seal ring completely encircles the second semiconductor die in the plan view.

6. The device of claim 1, wherein the semiconductor device comprises a first substrate and a through substrate via extending through the first substrate, further comprising:
a redistribution structure on a side of the semiconductor device opposite the local interconnect die, the redistribution structure electrically coupled to the through substrate via.

7. The device of claim 6, wherein the semiconductor device further comprises a guard ring surrounding the through substrate via in a top down view.

8. A device comprising:
a semiconductor device comprising:
a first seal ring surrounding a first region of active circuitry;
a second seal ring surrounding a second region of active circuitry; and
an intermediate region between the first seal ring and the second seal ring; and
a local interconnect die bonded to the semiconductor device, the local interconnect die overlapping the first seal ring, overlapping the intermediate region, and overlapping the second seal ring in a top down view, the local interconnect die electrically coupling the first region of active circuitry to the second region of active circuitry.

9. The device of claim 8, further comprising a first semiconductor die electrically coupled to the first region of active circuitry and a second semiconductor die electrically coupled to the second region of active circuitry.

10. The device of claim 9, wherein the local interconnect die electrically couples the first semiconductor die to the second semiconductor die through the first region of active circuitry and the second region of active circuitry.

11. The device of claim 9, wherein the first seal ring completely encircles the first semiconductor die in the top down view, and the second seal ring completely encircles the second semiconductor die in the top down view.

12. The device of claim 9, further comprising an encapsulant laterally surrounding the first semiconductor die, the second semiconductor die, and the local interconnect die.

13. The device of claim 8, wherein the local interconnect die comprises a deep trench capacitor.

14. The device of claim 8, wherein the intermediate region is free of active circuitry.

15. A device comprising:
a semiconductor device comprising a first substrate, a first active circuitry on the first substrate, and a second active circuitry on the first substrate, wherein the semiconductor device is free of an electrical connection between the first active circuitry and the second active circuitry;
a local interconnect die bonded to the semiconductor device, the local interconnect die comprising an interconnect substrate, interconnect dielectric layers on the interconnect substrate, and interconnect metallization patterns within the interconnect dielectric layers, the interconnect metallization patterns electrically coupling the first active circuitry to the second active circuitry; and
a redistribution structure on the semiconductor device opposite the local interconnect die.

16. The device of claim 15, wherein the local interconnect die comprises a deep trench capacitor.

17. The device of claim 15, further comprising:
a first semiconductor die electrically coupled to the first active circuitry; and
a second semiconductor die electrically coupled to the second active circuitry.

18. The device of claim 17, further comprising:
an encapsulant laterally surrounding the first semiconductor die, the second semiconductor die, and the local interconnect die, wherein a surface of the encapsulant is level with a surface of the first semiconductor die, a surface of the second semiconductor die, and a surface of the local interconnect die, wherein the surface of the first semiconductor die, the surface of the second semiconductor die, and the surface of the local interconnect die face away from the semiconductor device.

19. The device of claim 15, wherein the semiconductor device further comprises a first seal ring surrounding the first active circuitry and a second seal ring surrounding the second active circuitry.

20. The device of claim 19, wherein the local interconnect die overlaps the first seal ring and overlaps the second seal ring in a top down view.
